(19) United States
(12) Patent Application Publication
(10) Pub. No.: US 2020/0276761 A1
(43) Pub. Date: Sep. 3, 2020

(54) MULTI-MATERIAL MICROSTEREOLITHOGRAPHY USING INJECTION OF RESIN

(71) Applicant: University of Florida Research Foundation, Incorporated, Gainesville, FL (US)

(72) Inventors: Toshikazu Nishida, Gainesville, FL (US); Aftab A. Bhanvadia, Gainesville, FL (US); Raphael Puzio, Allen, TX (US)

(21) Appl. No.: 16/764,214

(22) PCT Filed: Jan. 11, 2019
(86) PCT No.: PCT/US2019/013160

§ 371 Date: May 14, 2020

Related U.S. Application Data
(60) Provisional application No. 62/616,671, filed on Jan. 12, 2018.

(51) Int. Cl. B29C 64/336; B29C 64/129; B29C 64/245; G03F 7/20; G03F 7/00

(52) U.S. Cl. CPC B29C 64/336; B29C 64/129; G03F 7/0037; G03F 7/70416; B29C 64/245

(57) ABSTRACT

Provided herein is an improved device and method of manufacturing multi-materials 3D objects. The improved device and method inject liquid monomer through a porous substrate to the desired locations along the substrate. The liquid monomer is polymerized by exposure to light to form a solid polymer. Different liquid monomers can be sequentially injected into through the porous substrate to the desired locations along the substrate for formation of 3D objects formed of different polymers.

### CROSS-REFERENCE TO RELATED APPLICATIONS

This application claims priority to and the benefit of U.S. Provisional Patent Application Ser. No. 62/616,671, entitled “Multi-Material Microstereolithography Using Injection of Resin” and filed on Jan. 12, 2018, the entire contents of which are hereby incorporated by reference.

### BACKGROUND

Ultra violet (UV) curable polymer based additive manufacturing is enabled by polymerization of liquid monomer into solid polymer when exposed to patterned UV light. In existing methods of microstereolithography, the bulk liquid monomer is contained in a tank before polymerization. During the growth process, the liquid monomer immediately adjacent to the solid boundary is polymerized to become a solid. The source of liquid monomer in the immediately adjacent layer is from the bulk liquid monomer contained in the tank. Applicant has identified a number of deficiencies and problems associated with conventional additive manufacturing. Through applied effort, ingenuity, and innovation, many of these identified problems have been solved by developing solutions that are included in embodiments of the present invention, many examples of which are described in detail herein.

### BRIEF SUMMARY

Embodiments of the present disclosure provide novel and advantageous microstereolithography devices and methods that selectively inject a plurality of liquid monomers through a porous substrate.

Embodiments provided herein are directed to a device for additive manufacturing. The device may include a containment vessel and a substrate disposed in the containment vessel and having a first substrate surface. In some embodiments, at least a portion of the substrate is a porous substrate and the device is configured to inject a liquid monomer through the porous substrate such that the liquid monomer is polymerized to form a solid polymer on the portion of the substrate that is the porous substrate. In some embodiments, the device includes a substrate holder attached to the substrate, wherein the substrate holder includes one or more channels for the liquid monomer to flow through the substrate holder to the substrate. In some embodiments, the device further includes a liquid monomer reservoir accommodating the liquid monomer, at least one pump providing the liquid monomer to the substrate, and a channel connected to the pump and transferring the liquid monomer from the liquid monomer reservoir to the substrate. In some embodiments, the liquid monomer reservoir includes a first liquid monomer reservoir and a second liquid monomer reservoir. The first liquid monomer reservoir includes a first liquid monomer different from a second liquid monomer disposed in the second liquid monomer reservoir.

In some embodiments, the device is configured to inject a plurality of liquid monomers through the porous substrate. In some embodiments, the liquid monomer reservoir includes a first liquid monomer reservoir and a second liquid monomer reservoir and the pump is configured to provide a first liquid monomer from the first liquid monomer reservoir, a second liquid monomer from the second liquid monomer reservoir, or combinations thereof to the substrate.

In some embodiments, the device includes a solid boundary disposed opposite the substrate and configured to expose a portion of the liquid monomer to polymerization light passing through the solid boundary. In some embodiments, the solid boundary includes a photomask, is transparent, or is both transparent and includes a photomask. In some embodiments, the device includes a light source configured to emit polymerization light to the liquid monomer, wherein the light source spatially controls polymerization of the liquid monomer to the solid polymer. A variety of light sources as disclosed herein may be used in the device to emit polymerization light to the liquid monomer. The position of the light source, wavelength of polymerization light, type and location of solid boundary and containment vessel, etc. may allow the emitted polymerization light to polymerize the liquid monomer.

In some embodiments, the device includes one or more inlet/outlet ports disposed in the containment vessel, in the solid boundary, or combinations thereof.

In some embodiments, the device may be configured to form a solid polymer comprising one or more channels for liquid monomer to flow through the one or more channels. For instance, in some embodiments, the liquid monomer may be polymerized to solid polymer at certain locations along the porous substrate using a photomask, patterned light, laser, etc. to spatially control the polymerization light to form one or more channels for liquid monomer to flow through the one or more channels in the solid polymer.

In some embodiments, the porous substrate includes a plurality of pores disposed equally over the porous substrate and the solid polymer forms over pores of the porous substrate. In some embodiments, the solid polymer forms over a portion of the substrate that is non-porous.

Embodiments of the present disclosure are also directed to a method of additive manufacturing comprising. The method may include injecting a first liquid monomer through a porous substrate to a porous substrate surface disposed in a containment vessel; exposing the first liquid monomer injected to the porous substrate surface to a polymerization light to form a first solid polymer disposed on the porous substrate surface; injecting a second liquid monomer through the porous substrate to the porous substrate surface disposed in the containment vessel; and exposing the second liquid monomer injected to the porous substrate surface to the polymerization light to form a second solid polymer disposed on the porous substrate surface. In some embodiments, the first liquid monomer is different from the second liquid monomer. In some embodiments, the second liquid monomer is injected immediately following injection of the first liquid monomer or simultaneously with injection of the first liquid monomer. In some embodiments, the containment vessel includes a solid boundary and injection of the first liquid monomer through the porous substrate forms a liquid bridge disposed between the porous substrate and the solid boundary. In some embodiments, the porous substrate includes a plurality of pores to allow the first liquid monomer and the second liquid monomer to flow through the plurality of pores to multiple locations along the porous substrate surface. In some embodiments, the method further includes draining excess liquid monomer from the containment vessel through one or more inlet/outlet ports disposed in the containment vessel, a solid boundary disposed in the containment vessel, or combinations thereof.

Embodiments of the present disclosure are also directed to 3D objects formed using the present device and method.

Embodiments of the present disclosure are also directed to a device for additive manufacturing, the device including a containment vessel; a substrate disposed in the containment vessel; and a solid boundary disposed in the device and opposite the substrate. The solid boundary defines one or more inlet/outlet ports, such as a single inlet/outlet port or a plurality of inlet/outlet ports, disposed in the solid boundary for injection of liquid monomer into the containment vessel. A plurality of inlet/outlet ports may be strategically placed in the solid boundary. The plurality of inlet/outlet ports may direct the desired injected liquid monomer to the region where polymerization is desired. The solid boundary is configured such that liquid monomer injected into the one or more inlet/outlet ports disposed in the solid boundary is polymerized to form a solid polymer when exposed to polymerization light through the solid boundary. The inlet/outlet ports may be placed in a region different from where polymerization is desired. That is, the inlet/outlet ports may not block the polymerization light. The inlet/outlet ports may also be used to drain fluid from the device.

The details of one or more embodiments of the subject matter described in this specification are set forth in the accompanying drawings and the description below. Other features, aspects, and advantages of the subject matter will become apparent from the description, the drawings, and the claims.

### BRIEF DESCRIPTION OF DRAWINGS

Having thus described the disclosure in general terms, reference will now be made to the accompanying drawings, which are not necessarily drawn to scale, and wherein:

FIG. 1 illustrates a conventional microstereolithography device;

FIG. 2 illustrates a microstereolithography device in accordance with embodiments discussed herein;

FIG. 3 illustrates a microstereolithography device in accordance with embodiments discussed herein;

FIG. 4(a) illustrates a microstereolithography device in accordance with embodiments discussed herein;

FIG. 4(b) illustrates a microstereolithography device in accordance with embodiments discussed herein;

FIG. 5 illustrates a light source of the device for polymerization according to embodiments of the present disclosure;

FIG. 6 illustrates a microstereolithography device in accordance with embodiments of the present disclosure;

FIGS. 7 and 8 illustrate an example of creating a multi-material three-dimensional (3D) object using injection approach in a top-down orientation of the process in accordance with embodiments of the present disclosure;

FIGS. 9(a)-9(c) show an example of the spatially selective UV light exposure scheme to fabricate a 3D object formed from multiple materials in accordance with embodiments of the present disclosure;

FIGS. 10 and 11 show another example of the injection method but in a bottom-up orientation for the process in accordance with embodiments of the present disclosure;

FIG. 12 shows an example of the separation, draining, and injection during a bottom-up orientation process in accordance with embodiments of the present disclosure;

FIG. 13 shows another example of a bottom-up method for injection in accordance with embodiments of the present disclosure;

FIG. 14 shows an example device and method incorporating an inert immiscible liquid in accordance with embodiments disclosed herein;

FIG. 15 illustrates an example of how the solid polymer may be utilized as an inlet/outlet port in accordance with embodiments disclosed herein;

FIG. 16 shows various examples of substrates and substrate holders in accordance with embodiments disclosed herein;

FIG. 17 illustrates an example using pump with multiple channels in accordance with embodiments disclosed herein;

FIG. 18 illustrates an example of passive draining in a top-down orientation in accordance with embodiments disclosed herein;

FIG. 19 illustrates an example in which the inlet/outlet port is a microfluidic channel connected to a tube that is connected to a pump and a third liquid monomer reservoir containing third liquid monomer in accordance with embodiments disclosed herein;

FIG. 20 shows an example of operations that may be performed during the present method in accordance with embodiments disclosed herein;

FIGS. 21(a) and 21(b) are examples of porous substrates attached to substrate holders in accordance with embodiments of the present disclosure;

FIG. 22 shows the injection of fluid through the substrate holder and porous substrate using a pump in accordance with embodiments of the present disclosure;

FIG. 23 shows an example apparatus for a bottom-up orientation in accordance with embodiments of the present disclosure;

FIG. 24 shows a bottom view of apparatus shown in FIG. 23 in accordance with embodiments of the present disclosure;

FIGS. 25(a)-25(c) show an example 3D object fabricated using the injection approach in accordance with embodiments of the present disclosure;

FIGS. 26(a)-26(d) are a series of chronological pictures of the injection process in a top-down orientation in accordance with embodiments of the present disclosure;

FIGS. 27 and 28 show examples of a microstereolithography device according to embodiments of the present disclosure;

FIG. 29 shows an example of a substrate holder of a microstereolithography device according to embodiments of the present disclosure;

FIG. 30 shows an example of a solid polymer on a microstereolithography device according to embodiments of the present disclosure;

FIGS. 31 and 32 are computer-aided-design (CAD) models of a microstereolithography system for polymerization according to embodiments of the present disclosure;

FIGS. 33 and 34 are CAD models of a containment vessel of a microstereolithography device for polymerization according to embodiments of the present disclosure;

FIG. 35 shows a schematic of an image stitching of a microstereolithography device according to an embodiment of the present disclosure;

FIG. 36 shows a light source integrating galvo scanning mirrors for image stitching of FIG. 35 in accordance with embodiments discussed herein;

FIGS. 37(a)-37(c) show an example of a light source in accordance with embodiments discussed herein; and

FIG. 38 is a flowchart for an exemplary method in accordance with embodiments disclosed herein.

### DETAILED DESCRIPTION

Microstereolithography is a process where complex 3D objects can be grown in a layer-by-layer fashion (additive manufacturing). Traditionally, a liquid monomer (e.g., resin) undergoes polymerization (e.g., curing or solidification) when exposed to UV light. The exposed UV light may be a patterned light, allowing the solidified polymer to take the shape of the patterned light. The growth process may be layer-by-layer where each layer has a discrete thickness, and the process may continue until the desired thickness is achieved.

As used herein, the term “resin” and “monomer” may be used interchangeably. In some embodiments, a “resin” may be composed of monomer, photoinitiator, dye, absorber, loaded micro/nano particles, any other component desired for polymerization or the resulting 3D object, or combinations thereof. As used herein, a “liquid monomer” will generally be used to refer to the fluid that is used to form the solid polymer and may include the components listed above for a resin and any other additional component desired for the resulting 3D object. For instance, the liquid monomer may include one or more types of monomers, photoinitiators, dyes, absorbers, loaded micro/nano particles, any other component desired for polymerization or the resulting 3D object, or combinations thereof.

As used herein, the term “polymerization” or “curing” may refer to the process of converting liquid monomer into a “solid polymer.” The method may not be limited to creating “polymers” (e.g., “plastic”). The disclosed devices and methods may be used to create any 3D object out of, for example, metal, ceramic, etc., and combinations thereof. The materials may be modified to prepare the desired object from the desired material. Thus, while the reaction process (e.g., the process of converting a liquid component to a solid component) is generally referred to as polymerization and with reference to a liquid monomer, the disclosed devices and methods may be used to create any 3D object out of, for example, metal, ceramic, etc., and combinations thereof, and thus, would use liquid forms of these materials and convert such forms to solid to form the 3D object.

Reference may be made throughout the present disclosure to “UV light” as the light that initiates polymerization. However, the polymerization light may be of any wavelength (e.g., narrow or broad spectrum). That is, the disclosure may be applied to light of any wavelength. Further, the disclosed devices and methods are not limited to only light initiated polymerization and may be applied to other curing processes.

Stereolithography and microstereolithography (μSL) is one type of additive manufacturing. Microstereolithography is generally used to refer to the fabrication of objects on a micrometer scale. However, the method and its basic principles may be scalable to a macro scale (that is, stereolithography). Thus, stereolithography and microstereolithography may be used interchangeably throughout the present disclosure.

Existing resin based 3D printing approaches, specifically stereolithography, may only manufacture parts using a single material, thus limiting the use of parts to mostly structural applications. The present device and method allows for fabrication of multi-material components, thus allowing fabrication of heterogeneous parts. The ability to fabricate heterogeneous parts may allow for the manufacture of functional parts within a single process similar to monolithic semiconductor fabrication processing methods.

Disclosed herein is an improved device and method for the manufacture of 3D objects. The present device and method may allow for the manufacture of 3D objects from multiple materials and complex geometries. The present device and method may allow for improved efficiency of such production with improved draining and injection of liquid monomer without the concern for cross-contamination of liquid monomers when alternating between materials. The present device and method may reduce excess liquid monomer as well as washing solvents or materials used to prevent cross-contamination of liquid monomers. For example, in some embodiments, washing solvent or other material for washing may be avoided completely. The present device and method is both flexible in the orientation of the production method, allowing for various orientations, and flexible in the geometries allowable for the resulting 3D object. The present device and method may have many applications in the additive manufacturing field.

As used herein, a “porous substrate” generally refers to a substrate sufficiently permeable to allow the injected liquid monomer to pass through the substrate. The porous substrate may be blocked by material disposed on one side of the substrate, for instance when the solid polymer is formed on a portion of the porous substrate over pores of the porous substrate, but would still be considered porous as the injected liquid monomer can enter the substrate and flow into the substrate and out through other pores of the porous substrate. Embodiments disclosed herein may utilize a porous substrate when injecting liquid monomer. Such porous substrate allows for flexibility of the formation of the solid polymer by providing various paths for the injected liquid monomer to flow, where such paths may be changed during formation of the solid polymer (e.g., as pores are blocked by formation of solid polymer, more of the liquid monomer may flow through other pores in the porous substrate). In some embodiments, the porous substrate may include interconnected pores providing a variety of connecting flowpaths for the liquid monomer to travel through the substrate. For instance, in some embodiments, injected liquid monomer may flow through the porous substrate where there is no solid polymer has been formed. In some embodiments, the porous substrate includes pores over the entire surface of the porous substrate and on the side edges of the substrate. Therefore, liquid monomer may flow from the sides and edges of the porous substrate.

The porous substrate may improve the efficiency of the method of manufacture by more efficiently directing the liquid monomer to the gap in which the liquid monomer is to be exposed to polymerization light thereby reducing excess liquid monomer waste. The porous substrate may reduce resources and time needed for draining the excess liquid monomer due to the reduced amount of excess liquid monomer. Further, a second liquid monomer may be injected into the same porous substrate without cleaning the substrate after using a first liquid monomer. The second liquid monomer sufficiently pushes out any residue of the first liquid monomer in the pores of the porous substrate.

The porous substrate may allow for fabrication of 3D objects in top-down or bottom-up orientation as well as left-right or right-left orientation.

The porous substrate may allow for an equally distributed flow of the injected liquid monomer throughout the entire substrate, as opposed, for example, to flow through a single channel which provides flow in only selected region where the channel is placed. When using a porous substrate, the liquid monomer may flow over the entire surface area of the porous substrate and the liquid monomer may flow through all the pores of the porous substrate equally, not just through a single channel. The porous substrate may allow for washing away unwanted oligomers or unwanted partially polymerized areas in the solid polymer (e.g., in channels formed in the solid polymer). Any residue on the porous substrate, 3D object, or solid boundary may be washed away by injection of new liquid monomer. In addition, when injected liquid monomer flowed through all the pores equally, stiction may be reduced during the separation of the solid polymer from the solid boundary due to fluidic pressure caused by the injected liquid monomer. The pores of the porous substrate may vary and may be less than about 200 microns in diameter, such as less than 100 microns, less than 50 microns, less than 20 microns, less than 2 microns in diameter. For instance, in some embodiments, the pores of the porous substrate are about 1 micron to about 200 microns in diameter, such as about 2 microns to about 100 microns in diameter, such as about 5 microns to about 50 microns in diameter. In some embodiments, the porous substrate is a porous stainless steel filters, foam metal, or other similar structure and may be a mesh or sieve type substrate, for example, a nylon mesh netting or fabric.

The porous substrate provides a surface for the solid polymer to bond or adhere to. The adhesion of the solid polymer to a substrate may be increased due to the use of a porous substrate because the solid polymer (e.g., the first layer of solid polymer formed) may be locked into the intricate random porous nature of the porous substrate. In additive manufacturing and microstereolithography, there may be a desire for strong adhesion of the solid polymer to the substrate due to issues with stiction between the solid polymer and a solid boundary. When liquid monomer becomes a solid polymer, the solid polymer may have strong stiction to the solid boundary. Due to the high stiction and repeated pulling/release operations for each layer, the solid polymer may debond or peel off from the substrate. When using a porous substrate in accordance with the present disclosure, there may be a stronger adhesion of the solid polymer to the porous substrate due to higher surface area and ability of the solid polymer to be interlocked into the pores of the porous substrate.

The porous substrate may also act as a filter and remove any unwanted solids or contaminants. For example, in a traditional approach, the liquid monomer may be expensive and the operator may want to reuse collected waste liquid monomer. The waste liquid monomer may contain partially polymerized solids or particles. When reusing waste liquid monomer (e.g., excess liquid monomer as disclosed herein), the porous substrate may filter unwanted contaminates.

As explained herein, the present device and method may allow for fabrication of heterogeneous 3D objects. That is, the present device and method may allow for the formation of 3D objects formed of multiple materials. The multiple materials may be different polymers formed into the same or different layers or features of the 3D object. Multiple types of liquid monomers may be injected without concern for cross-contamination if not desired. For instance, in some embodiments, the liquid monomers may be intentionally mixed. However, in some embodiments, it may be desired to not mix the liquid monomers such that a portion of the 3D object is formed of just the first liquid monomer (and not the second liquid monomer) while a portion of the 3D object is formed of just the second liquid monomer (and not the first liquid monomer). Thereby, heterogeneous 3D objects may be formed without concern for cross-contamination or additional washing or cleaning operations (beyond injecting the alternative liquid monomer). The porous substrate may allow for injection of the second liquid monomer without concern for cross-contamination. Due to the injection of the liquid monomer through the porous substrate, excess liquid monomer from both the first liquid monomer and the second liquid monomer may fall to the containment vessel. Embodiments disclosed herein may use the same containment vessel for the formation of the 3D object without concern for cross-contamination. In situ material changing may be performed. The first and second liquid monomer may sequentially be exposed to polymerization light to form portions of the 3D object.

In some embodiments, excess liquid monomer may be drained from the containment vessel. Such draining may occur by a variety of manners, both passive and active draining operations, and may further confirm the lack of cross-contamination over the various liquid monomers that may be injected into the containment vessel to form the 3D object.

In the present device and method, polymerization may occur at a solid-liquid interface (e.g., liquid monomer-solid boundary interface), a liquid-liquid interface (e.g., liquid monomer-inert immiscible liquid interface), or a liquid-gas interface (e.g., liquid monomer-air interface). Oxygen may be a polymerization inhibitor and, thus, an air-liquid monomer interface may not be used in some embodiments.

In the present device and method, different liquid monomers may be sequentially injected into the containment vessel without any intervening cleaning or washing step. With existing methods, there may be multiple containment vessels of liquid monomer, where each containment vessel contains a specific type of resin. With these traditional methods, one may need to 1) switch the containment vessel if it was desired to change the liquid monomer, and 2) one may need to wash or rinse away the 3D object before switching to the new liquid monomer and containment vessel. The 3D object may need to be washed to avoid any residue of the previous liquid monomer from appearing in the new containment vessel since the liquid monomer for polymerization is sourced from the bulk liquid monomer in the containment vessel. In the present device and method, different liquid monomers may be injected into the porous substrate sequentially and exposed to polymerization light to form a solid polymer including polymerized forms of the different liquid monomers without concern for cross-contamination. The source of liquid monomer (e.g., the liquid monomer reservoir) may not be contaminated when switching between liquid monomers.

Embodiments of the present disclosure provide methods and devices in which the liquid monomer layer immediately adjacent to the polymerization layer is sourced through injection of liquid monomer through a substrate (e.g., a porous substrate) and/or substrate holder. After flowing through the porous substrate, the injected liquid monomer may flow through any non-polymerized areas, including any channels in the solid polymer (if formed) and fill the finite gap between the solid boundary and the solid polymer. The excess liquid monomer may collect in the containment vessel. The freshly injected liquid monomer disposed in the gap between the solid boundary and previous solid polymer layer may be polymerized.

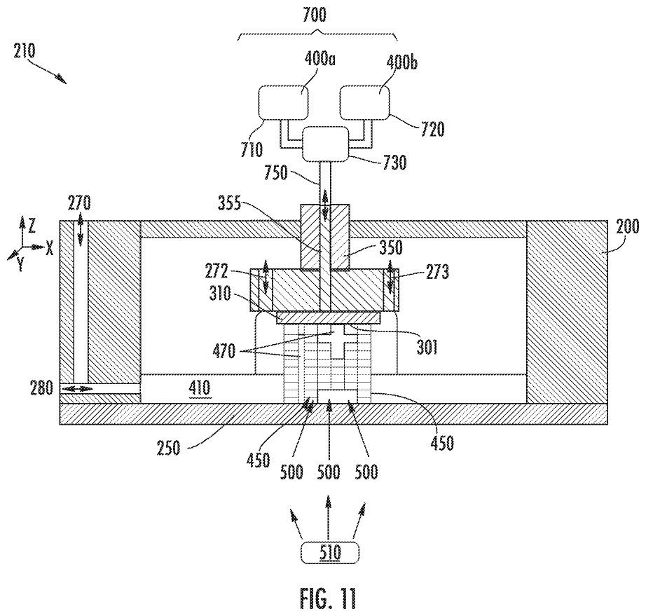

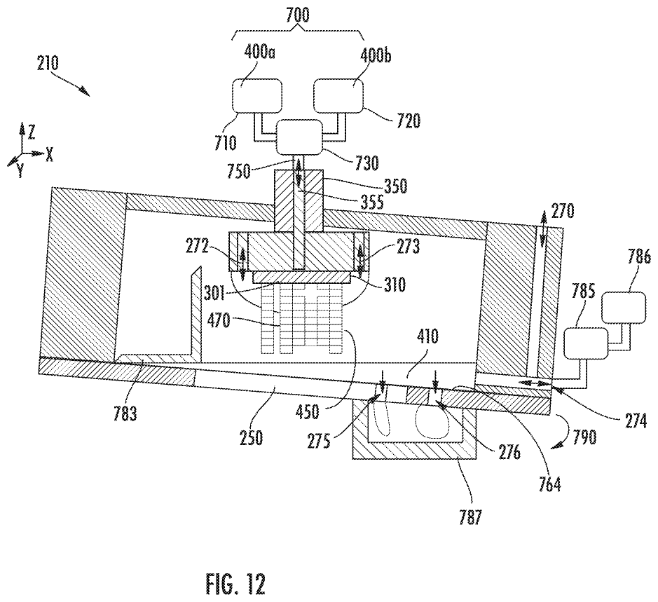

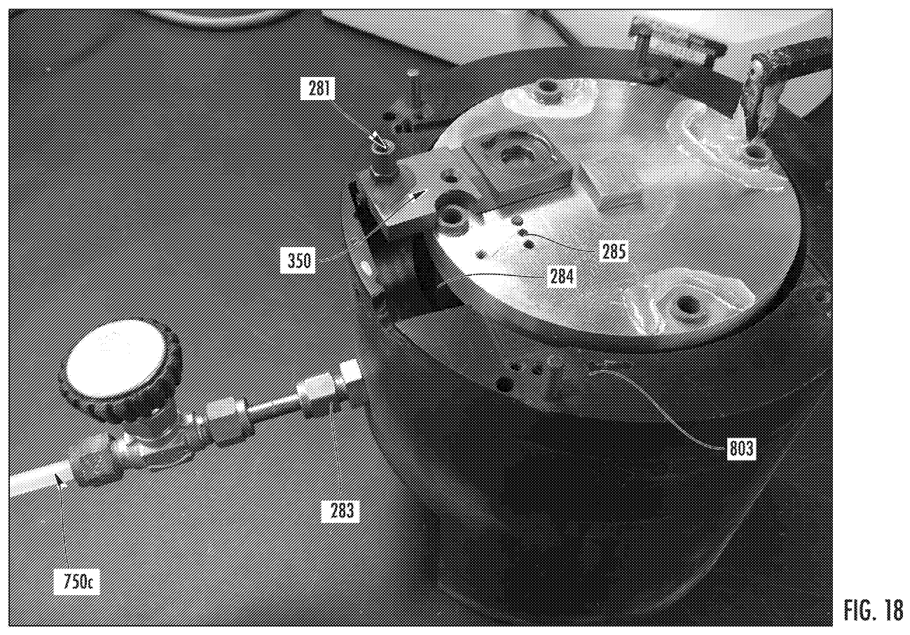

In the present device and method, a porous substrate may be used in addition to inlet/outlet ports disposed in the substrate and/or substrate holder. In some embodiments, inlet/outlet ports are disposed in various locations in the containment vessel to inject liquid monomer at these points in the containment vessel (see e.g., FIG. 12, tank drain port 276 and drain port 274). In some embodiments, inlet/outlet ports are disposed in various locations in the solid boundary to inject liquid monomer at these points in the device (see e.g., FIG. 19, microfluidic channel 286, FIG. 12, solid boundary drain port 275). In some embodiments, external flow paths or channels may be used to inject liquid monomer near the solid polymer (see e.g., FIG. 13, first inlet/outlet tube 791 and second inlet/outlet tube 792). Direct injection of the liquid monomer to the location of polymerization may improve the efficiency of the device, reduce waste, reduce the concern for cross-contamination, and allow for the simultaneous and/or sequential injection of a plurality of liquid monomers. Further, in some embodiments, the liquid monomer may be drained from various inlet/outlet ports, such as those discussed herein.

The present device and method provides improved methods and devices for forming 3D objects composed of multiple different materials. The different materials may be in the same or different layer of the 3D object or feature of the 3D object. A variety of geometries and resulting objects may be prepared using the disclosed device and method.

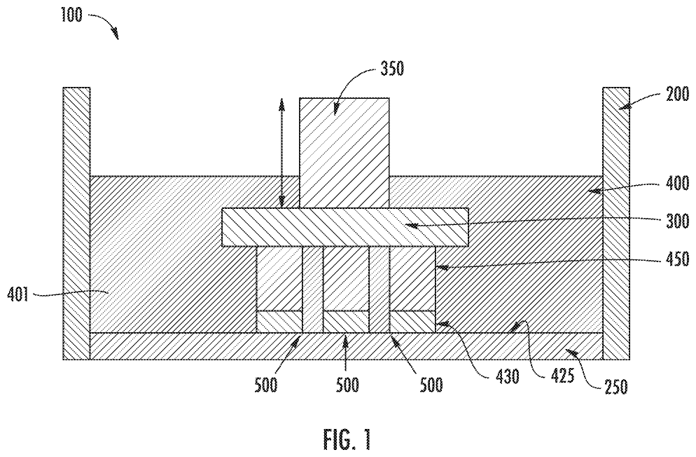

FIG. 1 illustrates a microstereolithography device according to traditional methods where polymerization occurs in a containment vessel filled with liquid monomer. In traditional methods of microstereolithography, the liquid monomer 400 is contained in a containment vessel 200 as shown in FIG. 1. Referring to FIG. 1, the microstereolithography device 100 includes a containment vessel 200 (e.g., a containment vessel or monomer bath) and a substrate 300 disposed in the containment vessel 200, wherein the containment vessel 200 includes a solid boundary 250 as a bottom plate such that a polymerization light 500 passes through the solid boundary 250. Before polymerization by the polymerization light 500, a liquid monomer 400 is poured into the containment vessel 200. An immediate layer 430 of the liquid monomer 400 corresponding to the polymerization light 500 becomes a solid polymer 450 when the polymerization light 500 is applied to the liquid monomer 400. When a substrate holder 350 connected to the substrate 300 moves in a vertical direction, the solid polymer 450 attached to the substrate 300 is pulled upwards, allowing more liquid monomer 400 to move under the solid polymer 450 becoming the immediate layer 430. The solid polymer 450 has a layer-by-layer structure. That is, during the layer-by-layer growth process, the immediate layer 430 of the liquid monomer 400 adjacent to the solid boundary 250 polymerized to become the solid polymer 450. The source of liquid monomer 400 in the immediate layer 430 is from the bulk liquid monomer 410 contained in the containment vessel 200. After polymerization of the immediate layer 430, the solid polymer 450 is mechanically separated from the solid boundary 250 using methods such as pulling, sliding, peeling, and tilting. The solid boundary 250 is often needed at the polymerization interface 425 to confine the polymerization boundaries and to prevent oxygen from diffusing from the environment into the polymerization reaction. Oxygen is a known inhibiter of the polymerization reaction of traditionally used UV curable polymer reactions.

In FIG. 1, when the solid polymer 450 needs to be made of more than one material, multiple types of monomers may be provided in the containment vessel 200 in sequence. That is, a first of liquid monomer 400 is provided into the containment vessel 200 as the bulk liquid monomer 401. The bulk liquid monomer 401 is used to become the solid polymer 450. The bulk liquid monomer 401 may be removed from the containment vessel 200, the containment vessel 200 may be cleaned, and a new type of liquid monomer (not illustrated) may be inserted into the containment vessel forming a new bulk liquid monomer. A stop-rinse process may be performed repeatedly for a multi-material solid polymer. The process is complex and a significant amount of bulk liquid monomer may be wasted.

Existing additive manufacturing methods, specifically (micro)stereolithography (uSL) are limited to “single” material fabrication. As shown in FIG. 1, a containment vessel 200 may be filled with liquid monomer 400 for polymerization. After exposure of a layer and formation of a solid polymer 450, the solid polymer 450 and substrate 300 are separated from the solid boundary 250 to form a new gap/layer. This gap gets filled with liquid monomer 400 from the rest of the liquid monomer 400 in the containment vessel 200. Such prior processes allow for the manufacture of a 3D object made of a single type of material (homogenous). In addition, in such processes, the liquid monomer 400 may need to be protected from ambient light to prevent premature polymerization or degradation of the liquid monomer 400. Such prior processes may involve a significant amount of wasted liquid monomer 400 as not all of the bulk liquid monomer 401 is used to form the solid polymer 450. In addition, in such prior processes, it is difficult to control the state in which the liquid monomer 400 is exposed to polymerization light 500.

The present device and method allow for the fabrication of multi-material 3D objects using stereolithography based additive manufacturing method. Stereolithography utilizes photo polymerization where a resin (typically liquid) is selectively exposed to UV light to create the 3D object.

The present device and method utilize an injection technique to carry out stereolithography and microstereolithography to fabricate 3D objects that are composed of multiple types of materials. The injection methods allow for delivery of multiple types of liquid monomer 400 at desired times and locations before exposure to polymerization light 500. Unlike existing methods, in the present device and method, the liquid monomer 400 is injected to the containment vessel 200 as the process is occurring.

The present device and method may allow multiple types of liquid monomer 400 to be used to fabricate 3D objects thus allowing heterogonous fabrication in a single process. This in-situ approach to changing the liquid monomer 400 also acts as a rinsing or washing operation. In some embodiments, there may be no need for an additional step of rinsing or washing the containment vessel 200. In some embodiments, there may be no need for cleaning of the containment vessel 200 separate from the injection of subsequent liquid monomer 400. In some embodiments, the liquid monomer 400 exposed to polymerization light 500 may be in the desired state considering the liquid monomer 400 is delivered to the polymerization interface 425 when needed rather than being stagnant in the containment vessel 200. This ensures the delivery of fresh liquid monomer 400 that is not degraded or does not include areas of pre-mature polymerization due to ambient exposure. For example, if a liquid monomer 400 needs to be maintained at 50° C., but the process is occurring at 25° C., the liquid monomer 400 may be injected at a temperature of 50° C. Or for example, if the liquid monomer 400 includes suspended nanoparticles, where the suspension is time varying, the liquid monomer 400 may be kept in an external reservoir in a state where the nanoparticles stay suspended and then injected when desired.

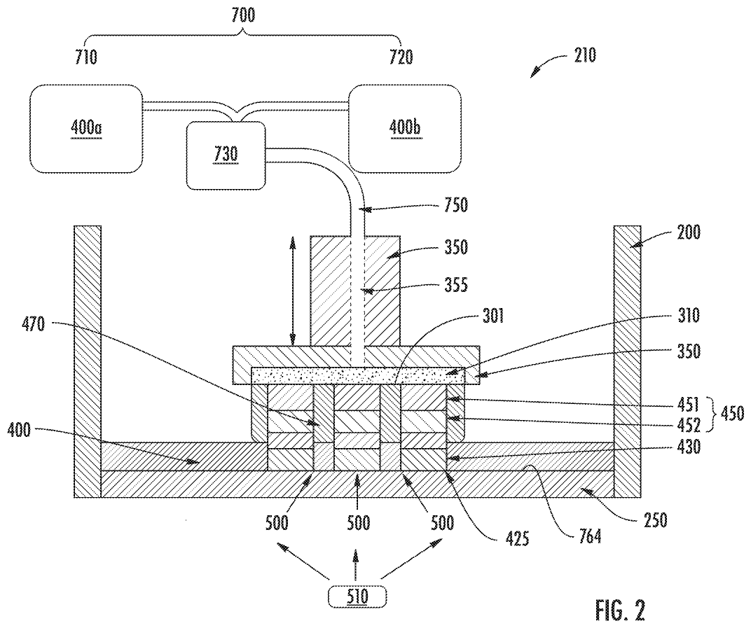

FIG. 2 illustrates a microstereolithography device according to embodiments of the present disclosure. Referring to FIG. 2, a microstereolithography device 210 includes a containment vessel 200 including a solid boundary 250, and a porous substrate 310 disposed in the containment vessel 200. The porous substrate 310 includes a first substrate surface 301 that faces the solid boundary 250.

The porous substrate 310 is configured such that the liquid monomer 400 passes through the porous substrate 310 and then is provided toward the solid boundary 250. The porous substrate 310 is attached to the substrate holder 350 and the porous substrate 310 can be moved in a vertical direction when the substrate holder 350 moves in the vertical direction. In the embodiments illustrated in FIG. 2, the substrate holder 350 includes a through hole 355 to provide the liquid monomer 400 to the porous substrate 310. The solid polymer 450 is formed on the porous substrate 310, specifically on the first substrate surface 301 of the porous substrate 310.

The microstereolithography device 210 further comprises a liquid monomer reservoir 700 including a first liquid monomer reservoir 710 and a second liquid monomer reservoir 720, a pump 730 selectively providing a first liquid monomer 400a of the first liquid monomer reservoir 710 or a second liquid monomer 400b of the second liquid monomer reservoir 720, and a tube 750 connected to the pump 730 in order to transfer the liquid monomer 400 selected from the first liquid monomer 400a and the second liquid monomer 400b to the substrate holder 350. The tube 750 passes through the through hole 355 of the substrate holder 350 or is connected to a pump 730 tubing injection port (not shown) of the substrate holder 350. While a tube may be referred to throughout the disclosure, any flowpath may be used and may be interchangeable with a channel or other cavity for fluid to flow. As used herein, channel refers to flow pathways for fluid.

The first liquid monomer 400a and the second liquid monomer 400b can be selectively injected through the porous substrate 310 for each layer to be polymerized, thereby enabling a truly heterogeneous additive manufacturing process where the solid polymer 450 is made of multiple materials instead of a single homogenous material. That is, the first liquid monomer 400a of the first liquid monomer reservoir 710 is injected through the porous substrate 310 for a first solid polymer 451 and the second liquid monomer 400b of the second liquid monomer reservoir 720 is injected through the porous substrate 310 for a second solid polymer 452. During manufacturing of the solid polymer 450 having multiple monomers, the manufacturing process may not need to be stopped to change the liquid monomer 400, and the containment vessel 200 may not need to be cleaned.

Further, in some embodiments, the first liquid monomer 400a and the second liquid monomer 400b can be injected simultaneously from the first liquid monomer reservoir 710 and the second liquid monomer reservoir 720, thereby providing a solid polymer 450 made of a mixture of the first and second liquid monomers 400a, 400b, respectively.

In the embodiment illustrated in FIG. 2, the solid boundary 250 is positioned at a bottom portion of the containment vessel 200 and functions as a bottom plate of the containment vessel 200. In this configuration, the liquid monomer 400 injected through the porous substrate 310 fills a gap between the solid boundary 250 and the porous substrate 310 and then the injected liquid monomer 400 is polymerized to become the solid polymer 450. After a layer of the solid polymer 450 is formed, newly injected liquid monomer 400 fills a gap between the solid boundary 250 and the solid polymer 450 and then this liquid monomer 400 becomes an immediate layer 430 that is a liquid monomer 400 to become solid polymer 450 in presence of polymerization light 500. When the immediate layer 430 is exposed to the polymerization light 500, the immediate layer 430 is polymerized. That is, the growth surface (i.e., solid boundary 250) is at the bottom 764 of the containment vessel 200 and the growth occurs from the bottom to the top at the polymerization interface 425. The excess liquid monomer 410 is washed away into the containment vessel 200, and the excess liquid monomer 410 in the containment vessel 200 can be drained through an outlet port (not shown).

During the layer-by-layer growth process, while an empty channel 470 in the solid polymer 450 provides a passage for the injected liquid monomer 400, the empty channel 470 may be filled with oligomers that are partially polymerized liquid monomer 400. The empty channel 470 may be cleared by washing away the oligomers using injection of the liquid monomer 400 (e.g., the second liquid monomer 400b after injection of the first liquid monomer 400b), thereby maintaining the clear empty channel 470 as desired. With the use of the porous substrate 310, the channel 470 may be cleared of unwanted residue. That is, the porous substrate 310 provides flow paths for the liquid monomer 400 to distribute along the substrate and enter any channels 470 disposed along the substrate to wash away any unwanted residue. Such may be difficult with a single injection flow path.

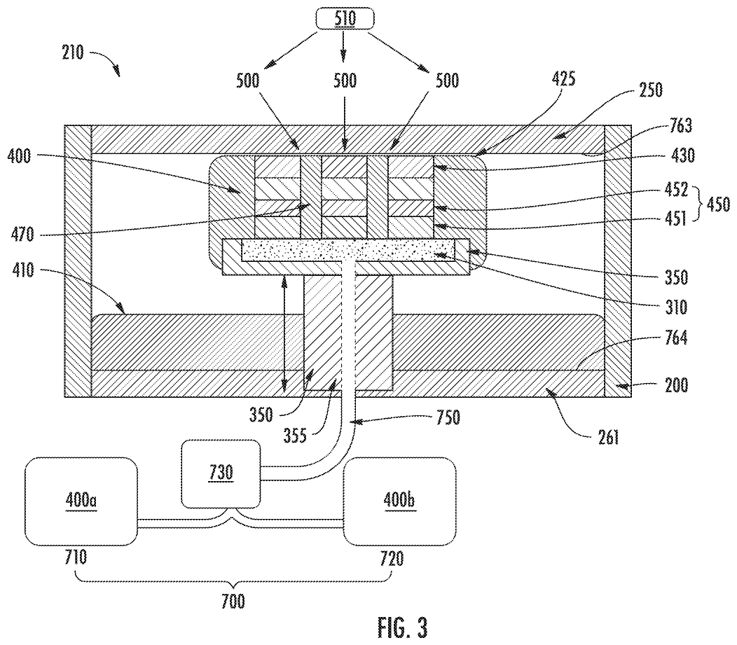

FIG. 3 shows a microstereolithography device according to an embodiment of the present device and method. Referring to FIG. 3, the containment vessel 200 includes a bottom plate 260 at a bottom 764 of the containment vessel 200 and the solid boundary 250 at a top portion. That is, the solid boundary 250 is at the top of the device 210, and the growth of the solid polymer 450 occurs from the top to the bottom of the device 210. The transparent solid boundary 250 can seal the containment vessel 200, thereby inhibiting contaminants from interfering polymerization. In this embodiment, the solid boundary 250 is a solid boundary 250 of which an area corresponding to the porous substrate 310 is transparent, but the solid boundary 250 can be replaced by a solid boundary 250 including a patterned photomask corresponding to the porous substrate 310. In some embodiments, the solid boundary 250 may be both transparent and include a patterned photomask. In addition, the solid boundary 250 can confine a layer of solid polymer 450 (e.g., first solid polymer 451 and second solid polymer 452) to a certain thickness. The porous substrate 310 and the substrate holder 350 are configured such that the liquid monomer 400 is injected from the bottom 764 to the top 763 of the containment vessel 200 through the porous substrate 310. Similar to the microstereolithography device 210 of FIG. 2, the liquid monomer 400 is provided from the liquid monomer reservoir 700 through the pump 730 and the tube 750. The liquid monomer reservoir 700 includes the first liquid monomer reservoir 710 and the second liquid monomer reservoir 720, and a selected liquid monomer 400 between the first liquid monomer 400a and the second liquid monomer 400b is injected through the pump 730, the tube 750, and the porous substrate 310.

The liquid monomer 400 to be polymerized is injected from the porous substrate 310, passes through the empty channel 470, and then reaches the solid boundary 250. As a result, the injected liquid monomer 400 fills a gap between the solid boundary 250 and the solid polymer 450, and becomes the immediate layer 430 that is the liquid monomer 400 to become the solid polymer 450 in the presence of polymerization light 500. The excess monomer 410 falls into the containment vessel 200, thus injection of another liquid monomer 400 after polymerization ensures a fresh and uncontaminated liquid monomer 400 at the immediate layer 430 for polymerization. That is, even if multiple liquid monomers 400 are sequentially injected as the immediate layer 430, each layer of the solid polymer 450 can remain high quality. Thus, multi-material monomer types are feasible without a stop-rinse-repeat process. Further, the present device and method may reduce excess liquid monomer 410 contained in the containment vessel 200. In addition, this configuration may reduce the exposure of the liquid monomer 400 to external contaminants by allowing it to be contained in a protected external reservoir, such as the liquid monomer reservoir 700.

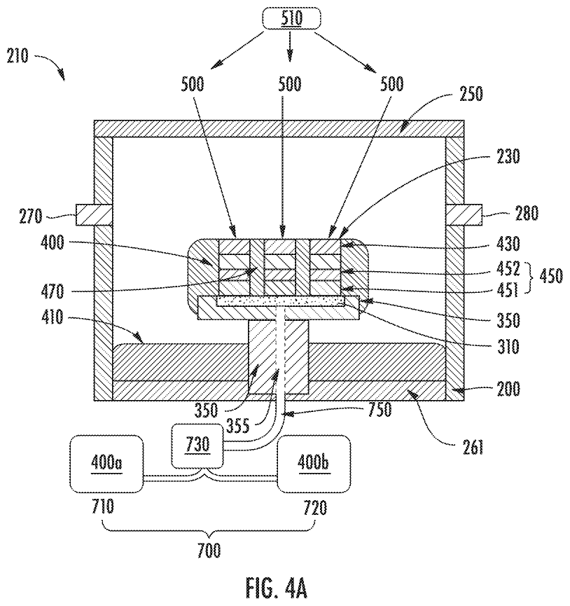

FIG. 4(a) shows a microstereolithography device according to an embodiment of the present disclosure. Referring to FIG. 4(a), the microstereolithography device 210 comprises a inert immiscible layer 230 between the solid boundary 250 and the immediate layer 430 by separating the injected liquid monomer 400 from the solid boundary 250. The inert immiscible layer 230 can be a vacuum or a gas such as nitrogen or air. The containment vessel 200 further includes inlet/outlet ports such as a first general purpose inlet/outlet port 270 and a second general purpose inlet/outlet port 280 for injecting and withdrawing solid, liquid, gas, or vacuum. For example, the first general purpose inlet/outlet port 270 may provide nitrogen for the inert immiscible layer 230 and the second general purpose inlet/outlet port 280 may be used for vacuum or for draining excess gas. When the second general purpose inlet/outlet port 280 is placed adjacent to the bottom plate 260, the excess liquid monomer 410 dripped into the containment vessel 200 may be drained through the second general purpose inlet/outlet port 280.

FIG. 4(b) illustrates a microstereolithography device according to an embodiment of the present disclosure. Referring to FIG. 4(b), the inert immiscible layer 230 is formed between the solid boundary 250 and the immediate layer 430 and between the solid boundary 250 and the excess liquid monomer 410. The inert immiscible layer 230 is a liquid in this embodiment. In addition, the inert liquid for the inert immiscible layer 230 can be provided by the pump 730. The microstereolithography device 210 can further include an inert immiscible reservoir (not shown) including a source of inert immiscible liquid that is configured to be provided to the containment vessel 200 through the pump 730 to form the inert immiscible layer 230.

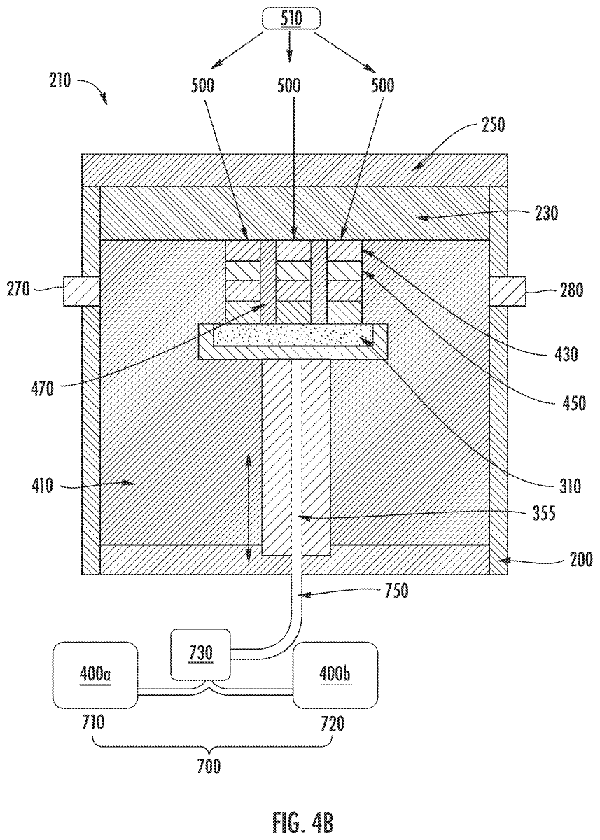

With respect to FIGS. 2-4(b), the immediate layer 430 of the liquid monomer 400 is exposed to the polymerization light 500 for polymerization provided by light source 510. The polymerization light 500 is a light having wavelength that initiates photo polymerization of liquid monomer 400. In particular, an Ultraviolet (UV) light can be used for polymerization. The UV light can be a non-patterned collimated light projected from a mercury arc lamp or an array of LED, or a patterned light projected from a projection system, such as a DLP projector. In addition, a laser can be used for a light source providing the polymerization light 500. Optics can be provided for collimating optics for the non-patterned light, for semi-collimating optics for the patterned light, and for magnifying or de-magnifying. The optics can include mirrors, prisms, and beam splitters. FIG. 5 illustrates a light source 510 of the device 210 for polymerization according to an embodiment of the present disclosure. Referring to FIG. 5, the light source 510 is a DPL 820 fitted with a projection lens 830. The DLP 820 emits a light 505 through a projection lens 830. Galvo scanning mirrors 810 reflect the emitted light 505 and provide the projected UV polymerization light 500. The galvo scanning mirrors 810 allow XY positioning of projected polymerization light 500 and may be used with a laser light instead of DLP projection light 505.

After each layer is polymerized in the microstereolithography device of FIGS. 2 and 3, the solid polymer 450 may be separated from the solid boundary 250 by applying mechanical force. When the liquid monomer 400 is injected through the channel 470, fluidic pressure force may be provided at the polymerization interface 425 of the solid polymer 450 and the solid boundary 250, and this fluidic pressure force may help separate the solid polymer 450.

The liquid monomer 400 may be injected in a vertical direction, such as from top to bottom or from bottom to top, as shown for instance in FIGS. 2-4(b). However, the injection direction of the liquid monomer 400 is not limited to a particular direction. For example, the liquid monomer 400 may be injected from left to right or from right to left.

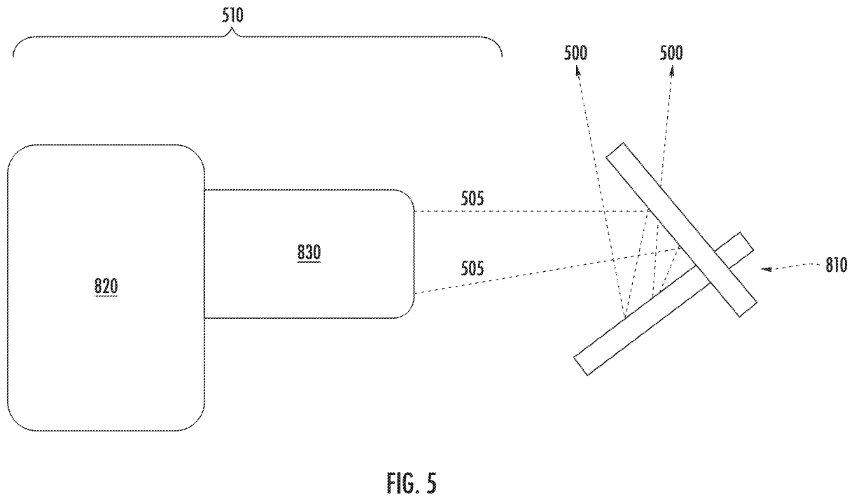

FIG. 6 illustrates an example approach to an injection method as disclosed herein. In the embodiment illustrated in FIG. 6, the liquid monomer 400 (e.g., first liquid monomer 400a and/or second liquid monomer 400b) is injected from pump 730. The injection occurs through the porous substrate 310 and substrate holder 350. The porous substrate 310 is porous to allow liquid monomer 400 to flow through the substrate. In the embodiment illustrated in FIG. 6, the containment vessel 200 also has inlet/outlet ports, including first and second general purpose inlet/outlet ports 270, 280, respectively, as well as a third general purpose inlet/outlet port 271. These inlet/outlet ports may be general purpose inlet/outlet ports for various functions such as injecting liquid monomer 400, draining excess liquid monomer 410, vacuum, injecting gasses, etc. When injected, the liquid monomer 400 flows into gap 760 formed between the solid boundary 250 and the solid polymer 450. Gap 760 may be filled with liquid monomer 400 due to surface forces (e.g., capillary forces) and the wettability of the solid boundary 250.

The liquid monomer 400 may also flow through channel 470 formed in the solid polymer 450 and any unpolymerized area on the porous substrate 310. Channel 470 may be intended or unintended and may be formed to direct the flow of liquid monomer 400 to the desired location (e.g., gap 760) and/or to control the liquid bridge 762. In some embodiments, channel 470 may be used when a second of liquid monomer 400 (e.g., first liquid monomer 400a or second liquid monomer 400b) is injected into the containment vessel 200.

In some embodiments, the liquid monomer 400 may also be injected through an inlet/outlet tube 766 placed near the solid boundary 250, the gap 760, and/or the solid polymer 450. The inlet/outlet tube 766 may be an inlet/outlet port for easier injection or draining excess liquid monomer 410. The injected liquid monomer 400 may form a liquid bridge 762 around the gap 760, solid boundary 250, solid polymer 450, and the porous substrate 310. This liquid bridge 762 may occur due to surface forces. Any excess liquid monomer 410 that is not part of the liquid bridge 762 may flow to the bottom 764 of the containment vessel 210. In some embodiments, when a second of liquid monomer 400 (e.g., first liquid monomer 400a or second liquid monomer 400b) is injected into the containment vessel 200, the first of liquid monomer 400 (e.g., first liquid monomer 400a or second liquid monomer 400b) may fall to the bottom 764 of containment vessel 210.

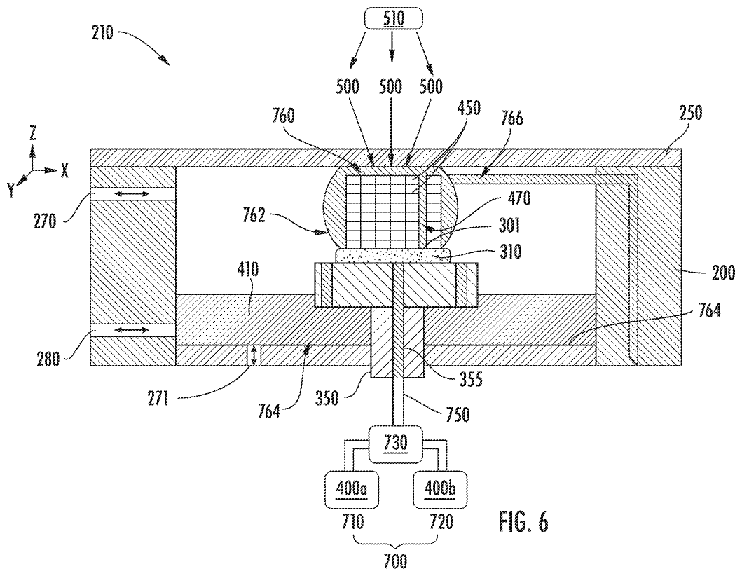

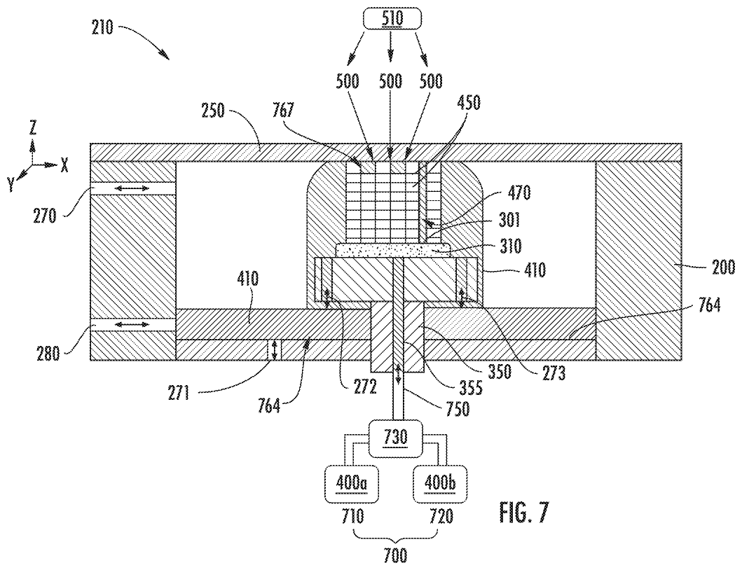

FIGS. 7 and 8 illustrate an example of creating multi-material 3D object using an injection approach in a top-down orientation in accordance with embodiments disclosed herein. In the embodiment illustrated in FIGS. 7 and 8, for a given layer, first liquid monomer 400a is exposed to spatially patterned polymerization light 500 to form a solid polymer 450. After formation of the solid polymer 450, the solid polymer 450 may be separated (not shown) from the solid boundary 250 resulting in the formation of a gap 760. Second liquid monomer 400b may be injected. Excess liquid monomer 410 of first liquid monomer 400a may be washed away and may fall to the bottom 764 of the containment vessel 200. The second liquid monomer 400b may be injected sufficiently such that the gap 760 has no remaining first liquid monomer 400a residue. After injection of second liquid monomer 400b, the second liquid monomer 400b may be exposed to polymerization light 500 to form solid polymer 450. As discussed herein for FIG. 6, any suitable mode of injection may be used. The collected excess liquid monomer 410 in the containment vessel 200 at the bottom 764 may be drained, for example, using another pump (not shown) or vacuum.

As shown in FIG. 7, there may be unpolymerized area 767 which may be intended to be polymerized after injection of a second of liquid monomer 400 (e.g., second liquid monomer 400b). That is, the polymerization light 500 may be patterned such that portions of the first liquid monomer 400a are not exposed to polymerization light 500 leaving unpolymerized area 767 along the surface of the solid polymer 450. As shown in FIG. 8, the unpolymerized area 767 may be filled with the second liquid monomer 400b, which is then exposed to polymerization light 500 to form new areas of solid polymer 450.

As also shown in FIGS. 7 and 8, the embodiment illustrated in FIGS. 7 and 8 includes inlet/outlet ports including first substrate holder inlet/outlet port 272 and second substrate holder inlet/outlet port 273 disposed in the substrate holder 350. These inlet/outlet ports may be flow paths for liquid monomer 400 to travel. The first substrate holder inlet/outlet port 272 and the second substrate holder inlet/outlet port 273 may be connected to a pump for injecting liquid monomer 400 and/or draining excess liquid monomer 410.

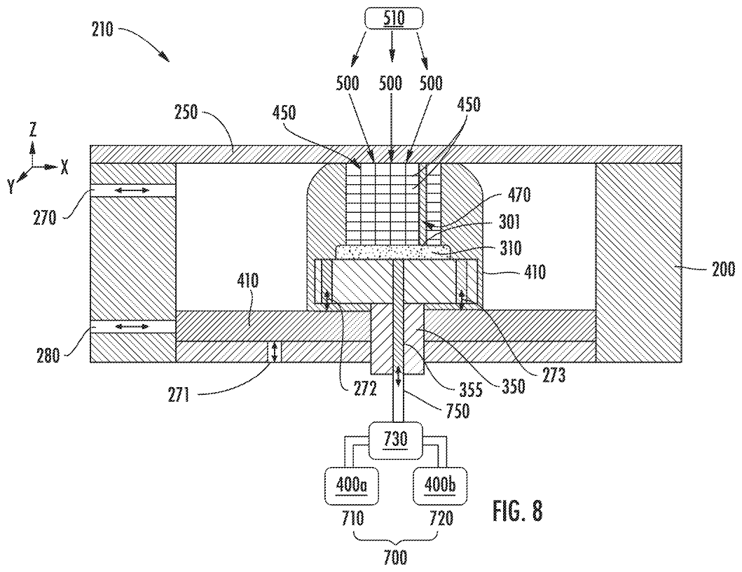

FIGS. 9(a)-9(c) show an example of the spatially selective UV light exposure scheme to fabricate a 3D object formed from multiple materials. In the embodiment illustrated in FIGS. 9(a)-9(c), the exposure method uses a projection or photomask based approach. FIG. 9(a) shows a cross section of the solid polymer 450 formed according to the embodiment illustrated in FIGS. 9(a)-9(c). In particular, the solid polymer 450 includes a first solid polymer 450a and a second solid polymer 450b, where first solid polymer 450a is formed of first liquid monomer 400a and second solid polymer 450b is formed of second liquid monomer 400b. FIG. 9(a) also includes channel 470 where no solid polymer forms. FIG. 9(b) illustrates an exposure pattern for the first liquid monomer 400a. As shown in FIG. 9(b), the exposure pattern includes an exposure region for the first liquid monomer 480a and an unexposed region for the first liquid monomer 481a. FIG. 9(c) illustrates an exposure pattern for the second liquid monomer 400b. As shown in FIG. 9(c), the exposure pattern includes an exposure region for the second liquid monomer 480b and an unexposed region for the second liquid monomer 481b. Use of the exposure patterns illustrated in FIGS. 9(b) and 9(c) result in the solid polymer 450 of FIG. 9(a).

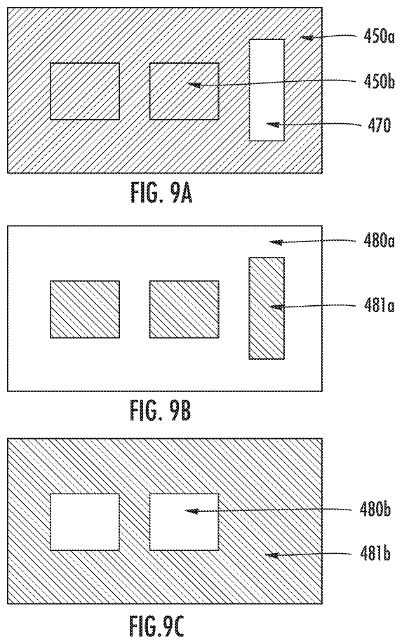

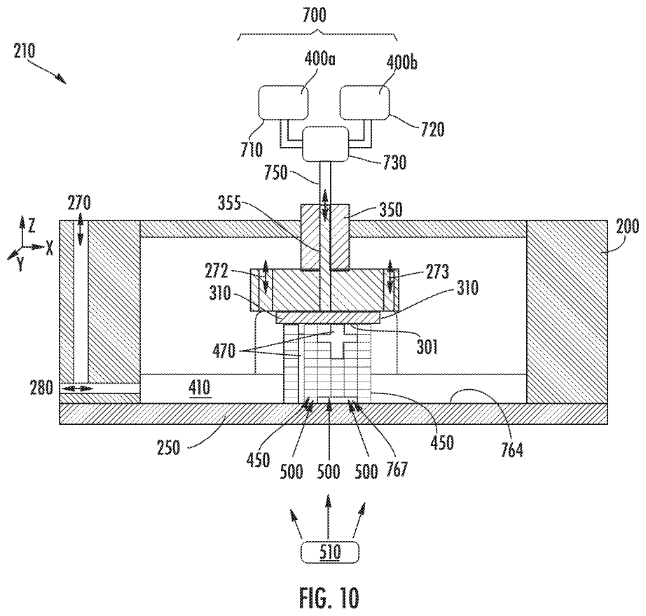

FIGS. 10 and 11 show another example of the injection method but in a bottom-up orientation in accordance with embodiments of the present disclosure. In the embodiment illustrated in FIG. 10, first liquid monomer 400a is selectively polymerized resulting in unpolymerized area 767 forming gap 760. Excess liquid monomer 410 of first liquid monomer 400a may fall to the bottom 764 of the containment vessel 200. The solid polymer 450 may be separated from the solid boundary 250 (e.g., as shown in FIG. 12) to form a larger gap 760. During and/or after separation, second liquid monomer 400b may be injected and first liquid monomer 400a may be drained (not shown). The injected second liquid monomer 400b may fall to the bottom 764 of containment vessel 200 resulting in the gap 760 being filled with second liquid monomer 400b. The solid polymer 450 may be moved back to its previous position of the layer, which is the same position where first liquid monomer 400a was exposed. The spatially selective exposure process may be repeated to solidify the second liquid monomer 400b in gap 760 as shown in FIG. 11.

In the embodiments illustrated in FIGS. 10 and 11, a plurality of channels 470 may be present in the solid polymer 450. The liquid monomer 400 (e.g., first liquid monomer 400a and/or second liquid monomer 400b) may flow through these channels 470.

FIG. 12 shows an exemplary separation process in accordance with embodiments disclosed herein. The solid polymer 450 may be separated from the solid boundary 250 by any suitable method, such as peeling, and may include draining of fluids and injection of additional fluids. The embodiment illustrated in FIG. 12 is a bottom-up orientation. Excess liquid monomer 410 may be drained and/or washed through any number of inlet/outlet ports (e.g., first, second, and third general purpose inlet/outlet ports 270, 280, and 271, respectively as disclosed herein) disposed throughout the device 210. The device 210 may include holes, voids, cavities, grooves, etc. (which all may be referred to as inlet/outlet ports) for draining and/or washing the device 210. The inlet/outlet ports may be strategically placed in the device, e.g., in the solid boundary 250 and/or the containment vessel 200 to guide and drain fluid.

In some embodiments, a squeegee or wiper blade 783 may move relative to the device 210. In some embodiments or the apparatus moves relative to the squeegee or wiper blade to help wipe off excess liquid monomer 410 and direct the excess liquid monomer 410 to an inlet/outlet port. In the embodiment illustrated in FIG. 12, the device 210 includes drain port 274 that may be an inlet/outlet port as discussed herein and may be connected to drain pump 785 which is connected to waste reservoir 786. As the first liquid monomer 400a is drained (e.g., using drain pump 785 into waste reservoir 786), injection of the second liquid monomer 400b may be started, which may operate to help rinse or wash away any residue of the first liquid monomer 400a. In some embodiments, the containment vessel may be tilted (shown by arrow 790) to help guide or push the liquid monomer 400 for drainage.

In the embodiment illustrated in FIG. 12, the containment vessel 200 includes tank drain port 276 defined in the bottom 764 of containment vessel 200 that drains the excess liquid monomer 410 to the liquid collection bin 787. The liquid collection bin 787 may be part of the containment vessel 200 or may be an attachment to the containment vessel 200. As shown in FIG. 12, the solid boundary 250 includes a solid boundary drain port 275 defined in the solid boundary 250 that drains the excess liquid monomer 410 to the liquid collection bin 787. Both drain port 276 and solid boundary drain port 275 may be inlet/outlet ports as discussed herein and may be disposed in various locations in the device 210.

FIG. 13 shows another example of a bottom-up method for injection. In this example, the solid boundary 250 is coated with a low surface energy coating 251 (e.g., TEFLON™ AF, polydimethylsiloxane (PDMS), CYTOP®, or combinations thereof). In some embodiments, the coating 251 is hydrophobic and thus reduces the wettability of the solid boundary 250. For instance, when liquid monomer 400 is injected into the containment vessel 200, the liquid monomer 400 may not spread over the entire surface of the solid boundary 250. Instead, the liquid monomer 400 may form a liquid bridge 762 around the solid polymer 450 and the porous substrate 310 due to poor wettability of the solid boundary 250 due to the coating 251. The liquid bridge 762 may also fill any gaps 760 between the solid polymer 450 and the solid boundary 250 coated with coating 251. The gap 760 may be filled with liquid monomer 400 to be polymerized after polymerization light 500 exposure. The gap 760 may be filled with liquid monomer 400 due to surface forces (e.g., capillary forces) and the surrounding liquid bridge 762. To maintain the shape of the liquid bridge 762, in some embodiments, each individual inlet/outlet ports or tubes (e.g., first and second substrate holder inlet/outlet ports 272 and 273, respectively; through hole 355; and drain port 274, tank drain port 276, and solid boundary drain port 275) may be continuously or intermittently inject or drain liquid monomer 400. In the embodiment illustrated in FIG. 13, the device 210 includes first inlet/outlet tube 791 and second inlet/outlet tube 792 disposed near the solid boundary 250 and near the substrate holder 350, respectively. The first inlet/outlet tube 791 may be used to drain excess liquid monomer 410.

In some embodiments, injection of the liquid monomer 400 as described herein may allow for in-situ dispensing of liquid monomer 400 (e.g., first liquid monomer 400a and/or second liquid monomer 400b) at a desired time. In addition, the disclosed method of injection allows for rinsing, washing, cleaning, and purging of the containment vessel 200. In some embodiments, there may be no need for manual material change over. In some embodiments, there may be no need for manual or external cleaning or rinsing beyond the injection of the next liquid monomer 400. However, in some embodiments, manual or external cleaning or rinsing may be performed in addition to the injection of the next liquid monomer 400.

In some embodiments, injection of the liquid monomer 400 (e.g., first liquid monomer 400a and/or second liquid monomer 400b) may allow for direct delivery of the desired liquid monomer 400 at the desired location or near the desired location where exposure to polymerization light 500 may take place. The desired location is typically the position along the porous substrate 310 where exposure will take place. The location may be the gap 760 between the solid boundary 250 and the solid polymer 450. When the gap 760 is filled with the desired liquid monomer 400, the liquid monomer 400 may be exposed with polymerization light 500 for solidification to occur. In some embodiments, the gap 760 may be filled because the liquid monomer 400 is a liquid and thus takes the form of the area it is injected into.

In some embodiments, injection may allow for delivery of the liquid monomer 400 at the time when needed. The liquid monomer 400 may be injected from the respective liquid monomer reservoir 700 (e.g., first liquid monomer reservoir 710 and/or second liquid monomer reservoir 720). That is, in some embodiments, the liquid monomer 400 may not be injected from the excess liquid monomer 410 contained in the containment vessel 200. The state of the liquid monomer 400 may be thus maintained or nearly the same as the state in which the liquid monomer 400 was in when disposed in the respective liquid monomer reservoir 700. For instance, the liquid monomer 400 may be maintained at 40° C. in the liquid monomer reservoir 700. When the liquid monomer 400 is injected from the liquid monomer reservoir 700 to the porous substrate 310, the liquid monomer 400 may still be at the same temperature at which it was contained in the respective liquid monomer reservoir 700. When the liquid monomer 400 is sourced from the containment vessel 200, the liquid monomer 400 may be at the temperature of the containment vessel 200 (e.g., ambient or the process operating temperature) (e.g., 25° C.) rather than a temperature specific for the liquid monomer 400. In some embodiments, the liquid monomer 400 may include suspended nanoparticles, which may be time or temperature varying. In such embodiments, the liquid monomer 400 may be continuously heated, cooled, stirred, or combinations thereof such that the liquid monomer 400 may be injected to the porous substrate 310 with the desired state of the suspended nanoparticles or other additives, such that the liquid monomer 400 is in this state when exposed to polymerization light 500.

In some embodiments, during injection, the liquid monomer 400 may be sourced from the respective liquid monomer reservoir 700 and injected at the desired location or near its desired location using pump 730. The flow of the liquid monomer 400 occurs through the various inlet/outlet ports, holes, tubes, channels, cavities, and porous substrate 310. These flow paths and inlet/outlet are chosen so that the delivery of the liquid monomer 400 occurs at the near location or near the desired location. For instance, the liquid monomer 400 may be injected from the liquid monomer reservoir 700 to the substrate holder 350 to the porous substrate 310, to the solid polymer 450, to the solid boundary 250, other locations in the containment vessel 200, or combinations thereof.

In some embodiments, a plurality of liquid monomers 400 (e.g., first liquid monomer 400a, second liquid monomer 400b, a third liquid monomer 400c, a forth liquid monomer (not illustrated), etc., and combinations thereof) may be injected simultaneously rather than a single liquid monomer (e.g., first liquid monomer 400a or second liquid monomer 400b, third liquid monomer 400c, a forth liquid monomer (not illustrated), etc.). In some embodiments, it may be desired to form a solid polymer 450 have a mixture of liquid monomers 400 (e.g., a heterogenous feature of the 3D object) in a portion of the solid polymer 450 or over the whole solid polymer 450.

In some embodiments, injecting the liquid monomer 400 may act as a purging, washing, rinsing, or cleaning operation. For instance, injecting the liquid monomer 400 may operate to rinse and/or wash away another liquid monomer (e.g., first liquid monomer 400a and/or second liquid monomer 400b) from the desired location. In some embodiments, injecting the liquid monomer 400 may operate to wash away oligomers (e.g., undesired reaction byproducts) or partially reacted liquid monomer 400 (e.g., partial solidification in locations where solidification is not desired). For example, when forming a 3D object that includes a dense array of tightly packed channels (holes), there may be partial solidification (e.g., gel-like features) in the channels. The partial solidification may be created due to reflection, diffraction, poor collimation, poor focusing, or combinations thereof of the polymerization light 500. In such embodiments, injecting liquid monomer 400 through the channels may help wash away any wanted residue.

In some embodiments, the injected components may not be reacted to form the solid polymer 450. For instance, in some embodiments, non-liquid monomers, such as solvents, may be injected to rinse away undesired liquid monomer 400 and/or residue. After injection of the solvent, for instance, the desired liquid monomer 400 may be injected such that that liquid monomer 400 may be exposed to polymerization light 500 to form solid polymer 450.

In some embodiments, any type of material may be injected to the containment vessel 200 (e.g., through the porous substrate 310). For instance, injection may be of other fluids (e.g., liquids or gasses), such as other resins, monomers, polymers, slurries, etc. that may be desired. These fluids may be reacted to form the solid polymer 450 or may be desired to be included within the solid polymer 450 as is. For example, 1,6-hexanediol (HDDA), poly(ethylene glycol) diacrylate (PEGDA), or combinations thereof may be added. A photoinitiator, such as 4,4′-bis(dimethylamino)benzophenone, may be added. An absorber or dye, such as 2-hydroxy-4-(octyloxy)benzophenone, may be added. Solvents or unreactive fluids may be injected as cleaning agents. For example, suitable solvents may include ethyl acetate, methanol, isopropyl alcohol, ethanol, and combinations thereof. Gasses may be injected to help purge the injection path or may act as additives in the liquid monomer 400 to control polymerization. For example, oxygen, nitrogen, argon, or combinations thereof may be injected into the containment vessel 200. For instance, as liquid monomer 400 (e.g., first liquid monomer 400a and/or second liquid monomer 400b) is injected, nitrogen (N2) gas may be injected in combination with the liquid monomer 400 to reduce the oxygen (O2) concentration. Oxygen may be an inhibitor of polymerization. Thus, decreasing the concentration of oxygen in the containment vessel 200 may increase the rate at which polymerization occurs.

In some embodiments, solids may be mixed with the fluids (e.g., liquid monomer 400). For example, solid nanoparticles may be suspended in the liquid monomer 400. While the liquid monomer 400 is injected into the containment vessel 200, the nanoparticles may be mixed with the liquid monomer 400 to form a slurry.

In some embodiments, the liquid monomer 400 is injected into a specific location along the solid polymer 450 for formation of the desired features. The porous substrate 310 as well as any inlet/outlet ports (e.g., first and second substrate holder inlet/outlet ports 272 and 273, respectively) may be configured to inject the liquid monomer 400 to the solid polymer 450 at a desired location.

In some embodiments, polymerization may occur between the solid boundary 250 and the solid polymer 450. In some embodiments, polymerization may occur at a liquid-liquid interface. For instance, polymerization may occur at a liquid monomer-inert immiscible liquid interface as disclosed in U.S Provisional Application No. 62/616,655. The disclosure of U.S Provisional Application No. 62/616,655, filed on Jan. 12, 2018, is incorporated herein in its entirety.

The gap 760 may be where the liquid monomer 400 is injected. The concept of the gap 760 is to bound the injected liquid monomer 400 to a desired location with a given height (layer thickness). Therefore, filling the gap 760 with liquid monomer 400 can be between two solids or can be between a liquid and solid.

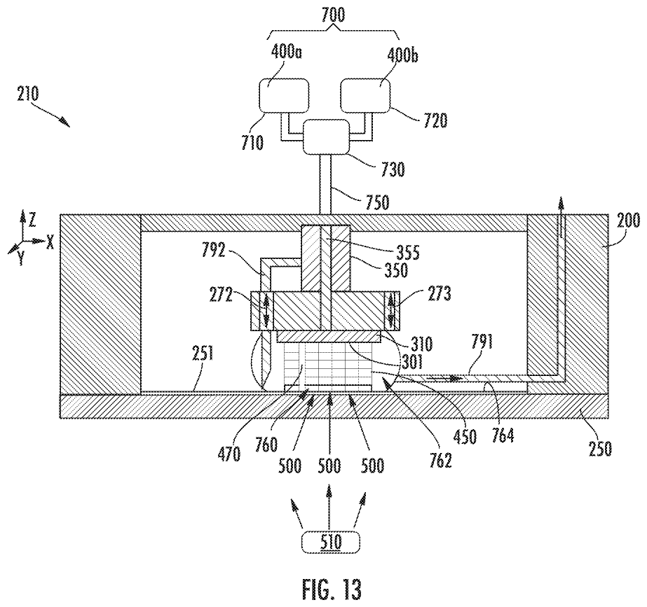

FIG. 14 shows an example device and method incorporating an inert immiscible liquid in accordance with embodiments disclosed herein. In the embodiment illustrated in FIG. 14, an inert immiscible liquid 230 is disposed between the solid boundary 250 and the liquid monomer 400 (e.g., the liquid monomer 400 filling the gap 760 and forming the liquid bridge 762). In the embodiment illustrated in FIG. 14, the liquid monomer 400 may not fully spread over the inert immiscible liquid 230 due to surface forces (e.g., surface tension). If more liquid monomer 400 is injected into the containment vessel 200, the liquid monomer 400 may spread over the inert immiscible liquid 230. The liquid monomer 400 fills the gap 760 and is then exposed to polymerization light 500 to become solid polymer 450.

In some embodiments, inlet/outlet ports may be used to guide fluid (e.g., liquid monomer 400) in a desired direction. As used herein, inlet/outlet ports may be a connection or pathway for fluid to flow through and may be bi-directional. The inlet/outlet ports may have an inlet and an outlet, where the inlet is an entrance into the flow path and the outlet is an exit from the flow path. In embodiments wherein the inlet/outlet ports are bi-directional, the inlet may be an entrance and an exit for the flow path through the inlet/outlet port and the outlet may be an entrance and an exit for the flow path through the inlet/outlet port. For instance, the direction of fluid flow may be in any direction (e.g., in or out). In the context of “injection”, the inlet or outlet may be considered the injection point. For example, the substrate holder 350 may have an inlet where tubing 750 for the pump 730 is connected. In the flow path through the substrate holder 350 (e.g., through hole 355), the liquid monomer 400 may flow from an inlet and finally end at the outlet. The outlet may be disposed where the liquid monomer 400 is desired to end. Depending on the orientation of the device 210, the liquid monomer 400 may then flow from the outlet to the actual desired location (e.g., the gap 760).

In the context of “draining”, the inlet or outlet may be considered as a drain point. For example, if pump 730 is running in a reverse direction, then all the excess liquid monomer 410 may flow from the porous substrate 310 through the substrate holder 350 and finally back to the liquid monomer reservoir 700.

In some embodiments, the inlet and/or outlet is a hole, port, void, connection point, tube, channel, tunnel, attachment point for tubes, hose, valves, etc., or combinations thereof. For instance, the inlet and/or outlet may be anywhere flow is injected and/or drained from. In some embodiments, the inlet and/or outlet may be incorporated into the 3D object.

In some embodiments, the inlet/outlet ports may be interconnected or disconnected to each other. For instance, if the inlet/outlet ports are disconnected from each other, each flow path may be used for only a specific liquid monomer 400 (e.g., first liquid monomer 400a or second liquid monomer 400b). Such configuration may provide spatial and/or direction control over where the liquid monomer 400 is injected or drained.

In some embodiments, the inlet/outlet ports may be interconnected. In some embodiments, interconnected the inlet/outlet ports may be used to mix liquid monomers 400 that may have been injected in different inlet and/or outlets. In some embodiments, the inlet/outlet ports may be disposed in the porous substrate 310, the substrate holder 350, the solid polymer 450, and combinations thereof.

In some embodiments, the solid polymer 450 may operate as an inlet/outlet port. For instance, as shown in FIG. 8, the solid polymer 450 includes channel 470. This channel 470 is an unsolidified area so that the porous substrate 310 may not be blocked and may allow fluid to flow through to the porous substrate 310 during injection.

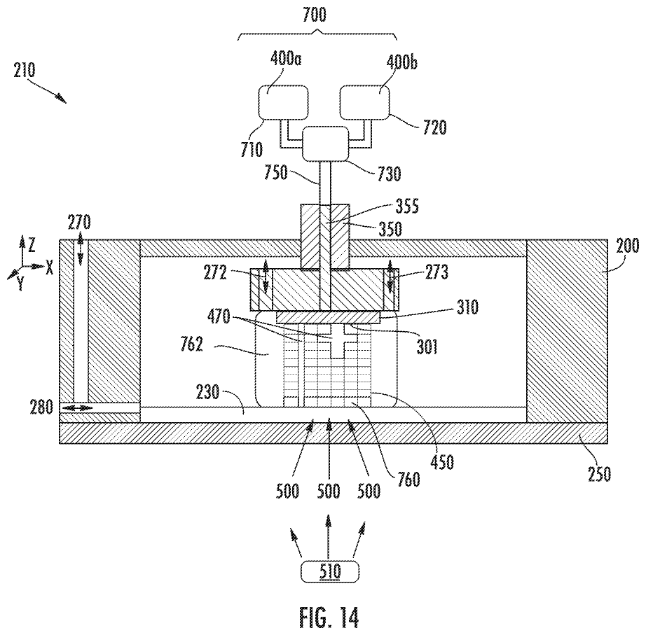

FIG. 15 illustrates an example of how the solid polymer 450 may be utilized as an inlet/outlet port. FIG. 15 shows a cross-section or top view of solid polymer 450 (including first solid polymer 450a, second solid polymer 450b, and third solid polymer 450c) being fabricated. As shown in FIG. 15, the substrate holder 350 has inlet/outlet ports disposed along the substrate holder 350. In particular, the substrate holder 350 includes first and second substrate holder inlet/outlet ports 272, 273, respectively, and third substrate holder inlet/outlet port 278 and forth substrate holder inlet/outlet port 279. The solid polymer 450 is created is on the porous substrate 310. Third solid polymer 450c includes an array of holes or channels 277 to direct the flow of injected liquid monomer 400 (e.g., first liquid monomer 400a and/or second liquid monomer 400b) through the porous substrate 310. The first and second solid polymers 450a, 450b may be blocking the flow of injected liquid monomer 400. The third solid polymer 450c may be connected to the second solid polymer 450b and the first solid polymer 450a or may be disconnected to the second solid polymer 450b and/or the first solid polymer 450a. For instance, if it is undesired to have the third solid polymer 450c as part of the resulting 3D object, the third liquid monomer 400c may be selected such that the resulting third solid polymer 450c may be easily removed after forming the first solid polymer 450a and the second solid polymer 450b. For example, the third liquid monomer 400c may be water soluble such that the third liquid monomer 400c may be dissolved away while first and second solid polymer 450a, 450b, remain in solid form.

Using the solid polymer 450 as the inlet/outlet ports may improve the injection efficiency. In the embodiment of FIG. 6, the fabrication orientation is top-down. Due to the liquid bridge 762 formed in FIG. 6, the gap 760 may be filled with the desired liquid monomer 400 after injection. In some embodiments, the liquid bridge 762 may not form. For instance, when the height of the solid polymer 450 becomes too large, the liquid bridge 762 may not form due to gravitational forces pulling the liquid monomer 400 down and causing it to drain to the bottom 764 of the containment vessel 200. In this case, a flow path for the injected liquid monomer 400 through, for instance, the channel 470 in the solid polymer 450 may help ensure the injected liquid monomer 400 reaches the top location where it is desired.

The inlet/outlet ports may be strategically placed to control the fluid (e.g., liquid monomer 400) flow. For instance, the inlet/outlet ports may be placed such that the fluid flows through the porous substrate 310 and/or the substrate holder 350. The inlet/outlet ports may be placed such that the fluid flows through the containment vessel 200. For example, the containment vessel 200 may include a plurality of inlet/outlet ports disposed within the walls of the containment vessel 200 to provide desired fluid in various locations in the device 210. In some embodiments, the inlet/outlet ports may be placed such that the fluid flows through the solid boundary 250. For instance, the solid boundary 250 may include an array of holes. The holes in the solid boundary 250 may not overlap areas where polymerization and UV exposure are to take place.

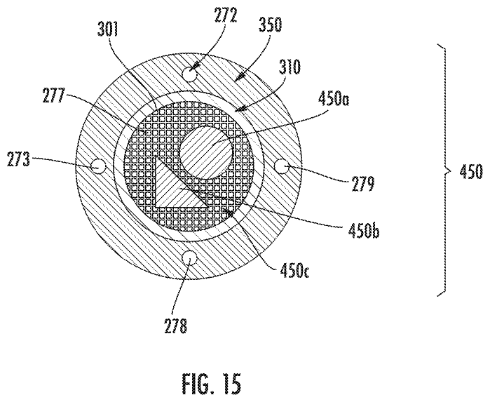

In some embodiments, the porous substrate 310 and substrate holder 350 may be disposed where the solid polymer 450 is intended to grow and be attached. FIG. 16 shows various examples of porous substrates 310 (e.g., porous substrates 310d and 310e) and substrate holders 350 (e.g., substrate holders 350a and 350b). In some embodiments, the porous substrate 310 and the substrate holder 350 may be a single component. For instance, in some embodiments, the substrate holder 350 may be a porous substrate 310. The configuration of the substrate holder 350 and porous substrate 310 may be adjusted depending on the desired 3D object and the configuration of the inlet/outlet ports.

In some embodiments, the porous substrate 310 may be porous. In some embodiments, the porous substrate 310 is porous and is disposed along the flow path of the liquid monomer 400. As used herein, the substrate is generally referred to as a porous substrate (e.g., porous substrate 310). However, the substrate may have non-porous portions or in some embodiments, may be a non-porous substrate (e.g., a silicon wafer). The disclosure provided herein may be applied to non-porous substrates. FIG. 16 illustrates example non-porous substrates 310a-310c. In such embodiments, the substrate holder 350 may be configured such that inlet/outlet ports for injecting the liquid monomer 400 (e.g., first and second substrate holder inlet/outlet ports 272, 273) are disposed in the substrate holder 350 such that these inlet/outlet ports are not blocked by the non-porous substrate 310. In FIG. 16, substrate holder inlet 281 is shown as well as substrate holder outlet 282 where liquid monomer 400 may pass through the substrate holder 350b.

In some embodiments, the porous substrate 310 and substrate holder 350 may include single or multiple inlet/outlet ports, channels, or other flow paths. In some embodiments, the porous substrate 310 may be porous stainless steel filters, stainless steel mesh, a woven stainless steel filter, woven nylon filter, or combinations thereof. In some embodiments, the non-porous substrate 310 may include aluminum, delrin, glass, silicon wafer, stainless steel, or combinations thereof. In some embodiments, combinations of porous and non-porous material may be used such that the substrate includes portions of porous material and portions of non-porous material.

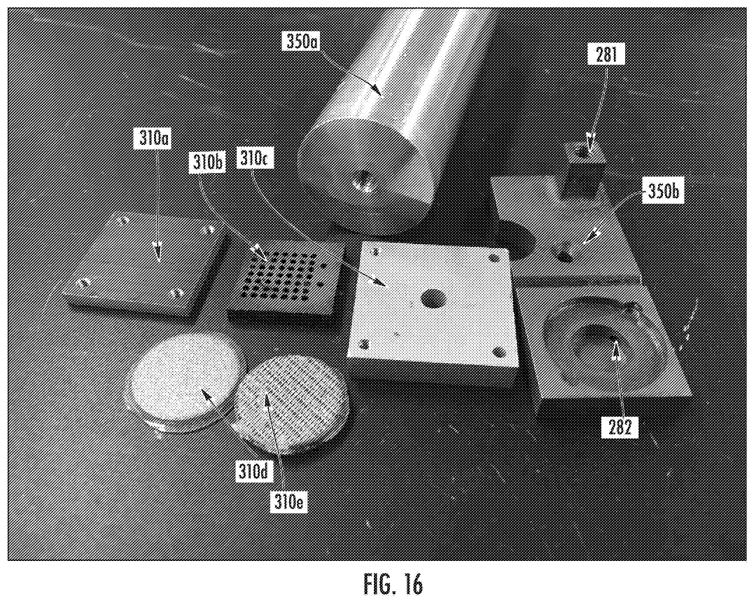

In some embodiments, the pump 730 may be a device used to push or direct the liquid monomer 400 from one location to another location. For instance, the pump 730 may be used to direct the liquid monomer 400 from an area of high pressure to low pressure and may be used to dispense the liquid monomer 400. The pump 730 may be any suitable pump, for instance, a peristaltic pump, HPLC pump, syringe pump, similar pumps, or combinations thereof. In some embodiments, a plurality of pumps 730 may be used. FIG. 17 illustrates an example using a single pump 730 that can be connected to multiple liquid monomer reservoirs 700. For instance, as shown in FIG. 17, the pump 730 includes reservoir inlets 731a, 731b, and 731c for connecting to various liquid monomer reservoirs 700. FIG. 17 also illustrates tube 750 that can be connected to the substrate holder 350 as discussed herein to inject liquid monomer 400 selectively from the various liquid monomer reservoirs 700 connected to pump 730.

In some embodiments, draining of the liquid monomer 400 may include collecting, removing, isolating liquid monomer 400, or combinations thereof, away from the desired location. In some embodiments, draining may be performed to prevent cross contamination of the liquid monomer 400 and ensure only the desired liquid monomer 400 is provided at a given location. In some embodiments, draining may be performed to ensure there is no residual or mixture of the previous liquid monomer 400. In some embodiments, the drained fluids (e.g., liquid monomer 400) can be recollected and reused or recycled back into the respective reservoir (e.g., liquid monomer reservoir 700).

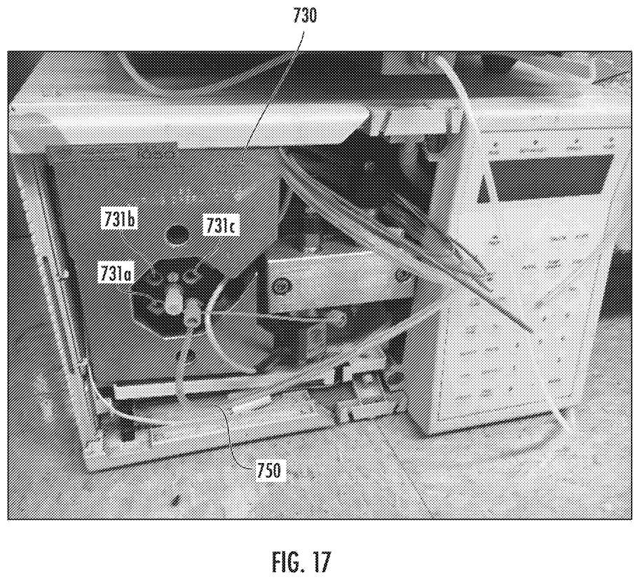

In some embodiments, draining may be passive. For example, in some embodiments, draining may be performed using solid boundary drain port 275 or tank drain port 276, for example, in FIG. 12. For example, excess liquid monomer 410 may be drained at the bottom 764 of the containment vessel 200 as shown in FIG. 7. FIG. 18 shows an experimental example of various passive drain points as conveyed in FIG. 7. In particular, FIG. 18 illustrates an example of passive draining in a top-down orientation. In FIG. 18, inlet/outlet ports including first top drain 284, second top drain 285, and main drain 283 are illustrated as well as tubing 750c and z-axis stage 803. In the embodiment illustrated in FIG. 18, first top drain 284 and second top drain 285 are draining holes (e.g., flow paths) that may allow excess liquid monomer 410 to fall to the bottom 764 of the containment vessel 200. The main drain 283 is connected to the containment vessel 200 to prevent the containment vessel 200 from overflowing. The device 210 may include a variety of inlet/outlet ports disposed in the device 210.

In some embodiments, draining may be active. For example, in some embodiments, draining may be performed through the inlet and outlet port that's connected to a pump 730. Pump 730 may act as a vacuum to suck out excess fluid (e.g., excess liquid monomer 410). In some embodiments, the injection process in reverse flow direction may operate as a draining process. For example in FIG. 13, when liquid monomer 400 is injected, the liquid monomer 400 flows through the porous substrate 310. In some embodiments, the direction of the flow of pump 730 may be changed to drain the liquid monomer 400 from the containment vessel 200.

In some embodiments, the mechanical design of the device 210 may be designed in a way to maximize the draining efficiency. In some embodiments, the orientation may be modified. For instance, in FIG. 7, the orientation of the device 210 is top-down, which may have a better draining efficiency as opposed to, for instance, the embodiment illustrated in FIG. 10, which has a bottom-up orientation and may need additional active or passive draining methods.

In some embodiments, the draining process may be mechanically assisted using other elements in the device 210 to improve the efficiency of the active or passive draining process. For example, the containment vessel 200 or device 210 may slide, tilt, rotate, spin, vibrate, etc. to help direct excess fluid (e.g., excess liquid monomer 410) out of the containment vessel 200 or device 210 to improve the efficiency of the active or passive draining process as shown, for instance, in FIG. 12.

In some embodiments, for example in FIG. 12, a wiper blade or squeegee 783 may sweep through the bottom 764 of the containment vessel 200 to help push the fluid (e.g., liquid monomer 400) in one direction or help wipe away any residue from the solid boundary 250 during the draining process. In some embodiments, the wiper blade or squeegee 783 may be used to help push one liquid monomer (e.g., first liquid monomer 400a and/or second liquid monomer 400b) in one direction or help wipe away any residue from the solid boundary 250 during the draining process while another liquid monomer 400 (e.g., first liquid monomer 400a and/or second liquid monomer 400b) is injected into the porous substrate 310.

In some embodiments, the solid boundary 250 may operate as a containment for fluid (e.g., liquid monomer 400) in the containment vessel 200. For instance, the solid boundary 250 may operate as containment for the fluid at the desired location in the device 210. In some embodiments, the solid boundary 250 may operate as a boundary for the gap 760 in which the injected liquid monomer 400 is filled. In some embodiments, the solid boundary 250 is optional and may not be present or needed. In some embodiments, the solid boundary 250 may be permeable. For example, in some embodiments, the solid boundary 250 may be permeable to certain desired gasses, such as oxygen, air, etc. In some embodiments, the solid boundary 250 may contain embedded or printed electronics. For example, in some embodiments, an array of micro heaters (e.g., microheater 260) may be disposed on or in the solid boundary 250 to control the temperature of the process. In some embodiments, the solid boundary 250 may contain an array of spiral conductive coils to generate magnetic field. In some embodiments, the solid boundary 250 may contain an array of capacitive electrodes to generate fringe electromagnetic fields. In some embodiments, the solid boundary 250 may contain an array of electrical contacts or electrodes or embedded sensors to detect temperature, pressure, etc. The solid boundary 250 can be a Light Emitting Device (LED) or a Liquid Cristal Display (LCD) type screen that emits patterned light itself. The solid boundary 250 can include a ground glass diffuser or holographic diffuser.

In some embodiments, the solid boundary 250 may be transparent to the wavelength of the polymerization light 500. In some embodiments, the solid boundary 250 may operate as a patterned photomask. In some embodiments, the solid boundary 250 may be attached to the containment vessel 200. In some embodiments, the solid boundary 250 may be a separate component from the containment vessel 200. In some embodiments, the solid boundary 250 may be integrated into the containment vessel 200. In some embodiments, the solid boundary 250 may move relative to the containment vessel 200, the porous substrate 310, the wiper blades, etc. In some embodiments, the configuration of the solid boundary 250 may be used to control or modify the draining process. For example, the solid boundary 250 may move relative to the wiper blade 783 and containment vessel 200 instead of the wiper blade 783 and containment vessel 200 moving relative to the solid boundary 250.

The solid boundary 250 may be of any suitable thickness. In some embodiments, the solid boundary 250 may be very thin and may operate as a permeable membrane or diaphragm.

In some embodiments, the solid boundary 250 may include inlet/outlet ports for injection or draining as long as the solid boundary 250 does not block, hinder, or negatively impact polymerization in the presence of polymerization light 500. Therefore, these inlet/outlet ports may be placed in a different locations away from where polymerization may take place. FIG. 19 illustrates an example in which the solid boundary 250 includes a microfluidic channel 286 connected to tube 750c that is connected to pump 730b and third liquid monomer reservoir 725 containing third liquid monomer 400c. In the embodiment illustrated in FIG. 19, the microfluidic channel 286 allows injection and/or draining of third liquid monomer 400c from the bottom 764 of the containment vessel 200 rather than through the substrate holder 350 and porous substrate 310.

The solid boundary 250 may include any suitable materials and may include a plurality of materials. In some embodiments, the solid boundary 250 may be coated with one or more materials. In some embodiments, the solid boundary 250 may be designed such that the surface properties of the solid boundary 250 may favor the injection process. For instance, in some embodiments, the solid boundary 250 may be coated with a low surface energy coating such as PDMS, TEFLON™ AF, CYTOP®, a silane, or combinations thereof to decrease the wettability (see e.g., coating 251 of FIG. 19).

In some embodiments, a liquid bridge 762 may be formed as shown, for instance, in FIG. 13. For instance, the solid boundary 250 may have a rough surface or may be coated with another material to increase wettability of the surface. For instance, such configuration may be favorable in a top-down fabrication orientation as shown in FIG. 6 because such configuration may help ensure the gap 760 is filled with the desired liquid monomer 400.

As shown, for instance, in FIG. 6 and FIG. 13, a liquid bridge 762 may form due to surface forces and wetting characteristics of the surfaces. A liquid bridge 762 is generally a liquid formation or connection of liquid between two solid objects.

In some embodiments, for instance, despite the coating 251 in FIG. 13, the liquid bridge 762 may disappear. For instance, in some embodiments, all of the fluid (e.g., liquid monomer 400) may fall to the bottom 264 of the containment vessel 200 depending on multiple factors. In some embodiments, these factors affect which forces (e.g., surface or gravitational forces) dominate. Thus, the liquid bridge 762 may or may not form. Factors include: the geometry of the 3D object (e.g., the height), the distance the porous substrate 310 and substrate holder 350 is away from the solid boundary 250; and injected fluid (e.g., liquid monomer 400) properties such as surface energy, viscosity, density, etc.

In some embodiments, the liquid bridge 762 may allow for a reduced amount of liquid monomer 400 needed for injection. In some embodiments, the liquid bridge 762 may not fully spread over the entire bottom 764 of the containment vessel 200 (e.g., FIG. 13). Such formation may reduce the need for excessive draining or actions needed for draining. The liquid bridge 762 may also provide a better determination of where the inlet/outlet ports may need to be placed.

In some embodiments, the formation of the liquid bridge 762 may be controlled or maintained. For example, the inlet/outlet ports may be used to continuously or intermittently inject and/or drain fluid (e.g., liquid monomer 400) from the containment vessel 200. The rate at which these occur and the placement of the inlet/outlet ports may provide better control over the liquid bridge. The liquid bridge 762 may be formed of one liquid monomer (e.g., first liquid monomer 400a) and then formed of another liquid monomer (e.g., second liquid monomer 400b) during formation of the solid polymer 450. In embodiments utilizing a porous substrate 310, the liquid bridge 762 may be easily prepared and maintained for multiple liquid monomers 400 over the course of formation of the 3D object.

The fabrication orientation may be in any direction: top-down, bottom-up, left-right, right-left. The injection or draining of liquid monomer 400 and other fluids may occur at any suitable time during the process and may be simultaneous in some embodiments. Injection and/or draining of the liquid monomer 400 may be continuous or intermittent. For instance, the liquid monomer 400 may be continuously injected and/or drained while the liquid monomer 400 is exposed to polymerization light 500. The substrate holder 350 may be continuously moved to allow for new liquid monomer 400 to be exposed to polymerization light 500. In such embodiments, multi-material solid polymer 450 may still be prepared with different liquid monomers 400 (e.g., first liquid monomer 400a and second liquid monomer 400b) injected and/or drained such that at least one of the liquid monomers 400 is being injected and/or drained while exposing the appropriate liquid monomer 400 to polymerization light 500.

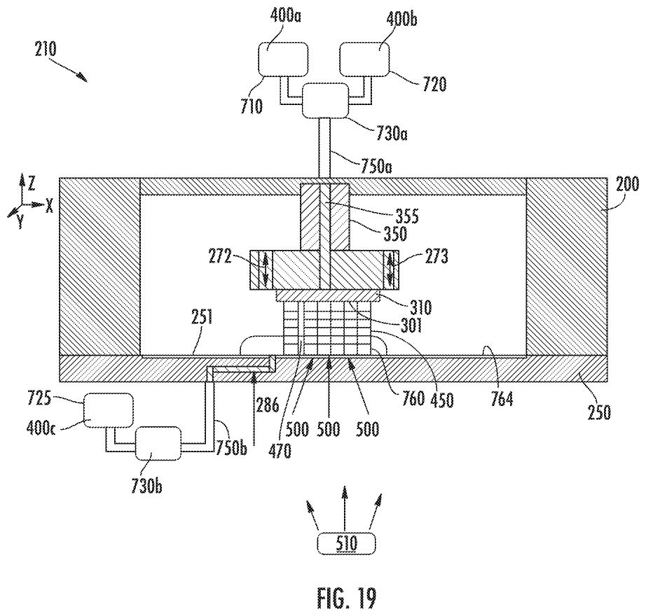

FIG. 20 shows an example of various operations that may be performed during the present method. As shown, any point during the present method (e.g., before and/or after exposure) and during the separation or peeling process, injection and/or draining may occur. In the embodiment illustrated in FIG. 20, the z-axis position of the porous substrate 310 is shown over time. First liquid monomer 400a is injected; then second liquid monomer 400b is injected; and then first liquid monomer 400a is injected again. Time 1 relates to the injection of the current liquid monomer 400 before exposure, time 2 relates to the patterned UV exposure, time 3 relates to after exposure, the injection of alternate liquid monomer 400 and draining of the previous liquid monomer 400, time 4 relates to moving the porous substrate 310 up while injecting alternate liquid monomer 400 and draining the previous liquid monomer 400, time 5 relates to injecting the alternate liquid monomer 400 and draining the previous liquid monomer 400 before moving the porous substrate 310 down, and time 6 relates to moving the substrate down while injecting the alternate liquid monomer 400. The new layer thickness is shown by T1.

In some embodiments, injection and/or draining may not occur. For instance, in embodiments where it is desired to use the same liquid monomer 400 for the next exposure to polymerization light 500, injection and/or draining may not occur. In some embodiments, the liquid monomer 400 may be sourced from excess liquid monomer 410 in containment vessel 200. In some embodiments, whether injection and/or draining is performed may depend on the orientation of the device 210. For example, in a top-down orientation, draining may not be needed, while injection may be needed. In a bottom-up orientation, neither draining nor injection may be needed since the liquid monomer 400 may be sourced from excess liquid monomer 410 in the containment vessel 200 when it is desired to use the same liquid monomer 400 for the next exposure to polymerization light 500.

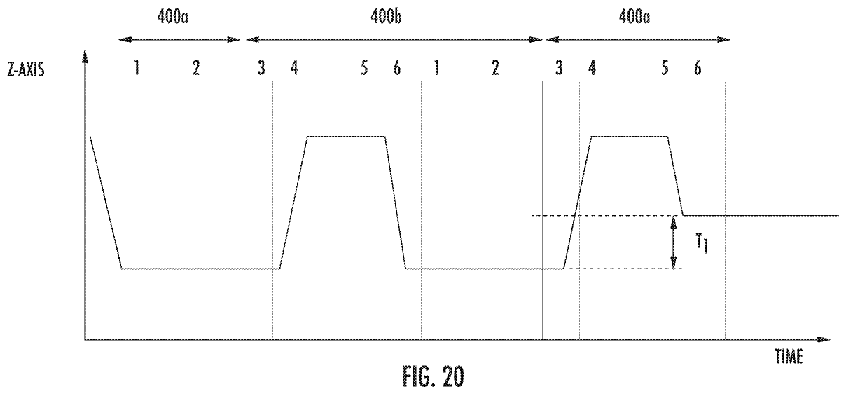

FIGS. 21(a) and 21(b) are examples of porous substrates 310f, 310g attached to substrate holders 350c, 350d. The substrate holder 350c of FIG. 21(a) includes through hole 355 and the substrate holder 350d of FIG. 21(b) includes a side substrate holder inlet/outlet port 287.

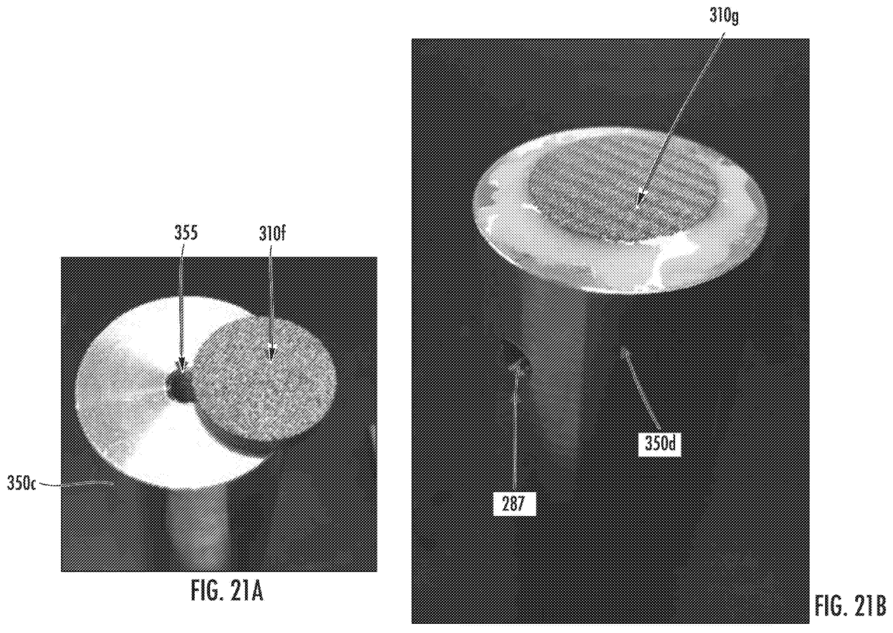

FIG. 22 shows the injection of fluid through the substrate holder 350 and porous substrate 310 using an external pump 730. The substrate holder 350 is connected to the pump 730 using tube 750.

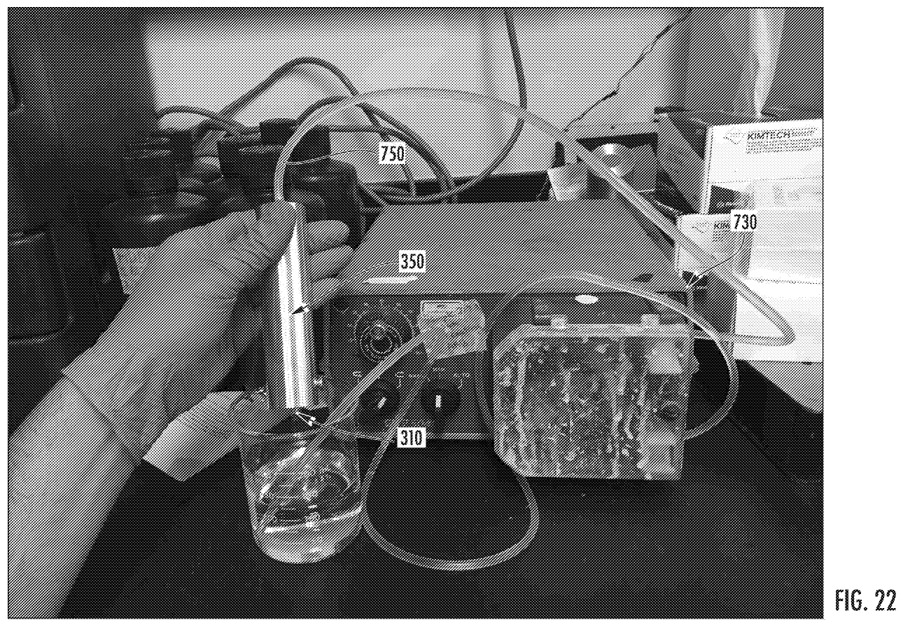

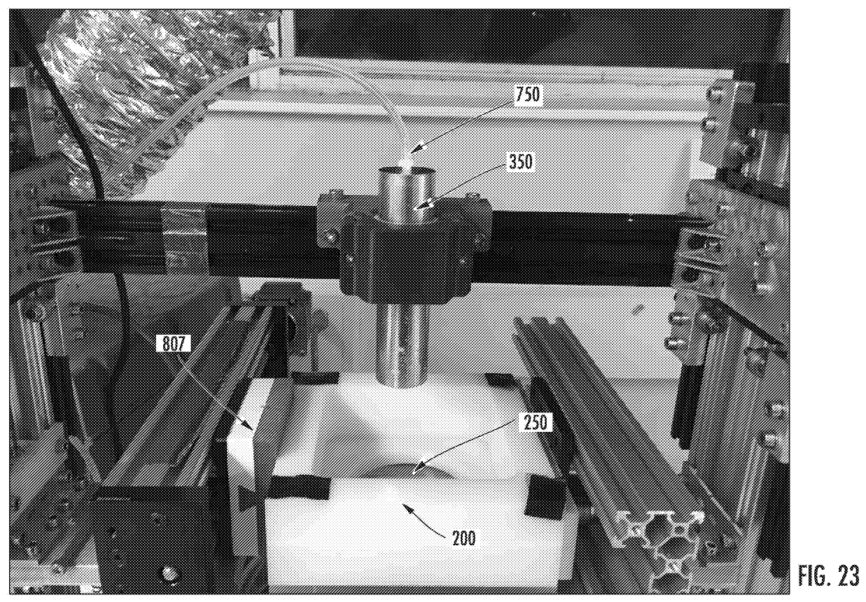

FIG. 23 shows an example apparatus for a bottom-up orientation, for instance, as shown in schematics of FIG. 10, FIG. 13, and FIG. 14. In the embodiment illustrated in FIG. 23, attachment device 807 is used to initiate mechanical manipulation of the containment vessel 200 (e.g., tilt, vibrate, rotate, etc.). FIG. 24 shows a bottom view of apparatus, for instance, as shown in FIG. 23. In particular, FIG. 24 shows a bottom view through the solid boundary 250 of an example device 210 with a liquid bridge 762. In this view, a liquid bridge 762 is visible, for instance, as conveyed in FIG. 13 and FIG. 14, and has not spread over the entire solid boundary 250. The liquid monomer 400 fills the gap 760 and is exposed to polymerization light 500.

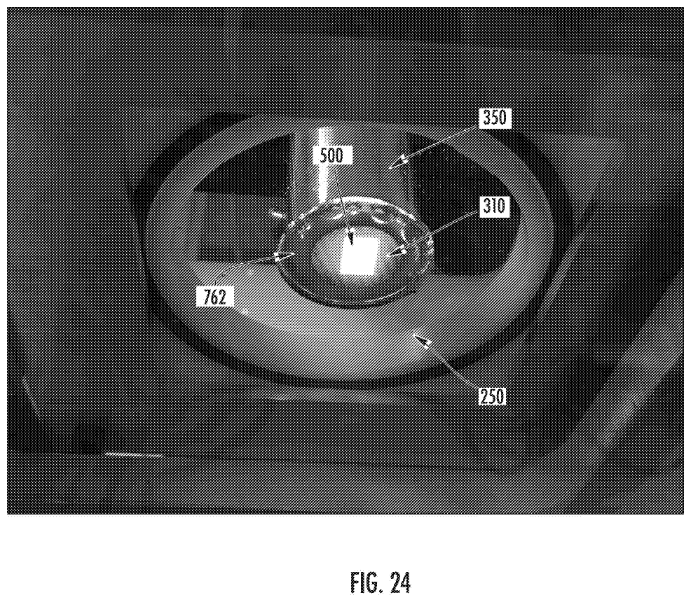

FIGS. 25(a)-25(c) show an example 3D object 600 fabricated using the injection approach. This 3D object 600 has an array of channels 470 of around 1 mm in length/width. The channels 470 may also operate as an inlet/outlet port allowing liquid monomer 400 from the porous substrate 310 through the channels 470.

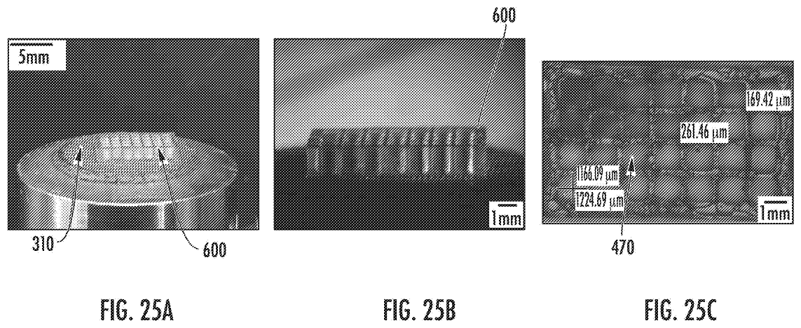

FIGS. 26(a)-26(d) are a series of chronological pictures (time-lapse) of the injection process in a top-down orientation. Time increases from FIG. 26(a) to FIG. 26(d). In the embodiment illustrated in FIGS. 26(a)-26(d), liquid monomer 400 is injected through the porous substrate 310 and through the channels 470 (not shown) formed in the solid polymer 450. Once the liquid monomer 400 reaches the top, the liquid monomer 400 forms a curved shape until gravitational forces dominate, resulting in excess liquid monomer 410 being drained to the bottom 764 of containment vessel 200. The series of pictures in FIGS. 26(a)-26(d) also convey how injection/draining can be used as a method to clean, rinse, wash, or combination thereof. For example, if the liquid monomer 400 used was first liquid monomer 400a, then second liquid monomer 400b can be injected, which causes first liquid monomer 400a to be washed away leaving only second liquid monomer 400b remaining. This operation ensures that when second liquid monomer 400b is being exposed to polymerization light 500 for solidification, the second liquid monomer 400b may have no residual or cross-contamination of the previous liquid monomer 400 (e.g., first liquid monomer 400a). In addition, the act of injection also ensure any residual oligomer (e.g., partially reacted liquid monomer 400) is washed away.

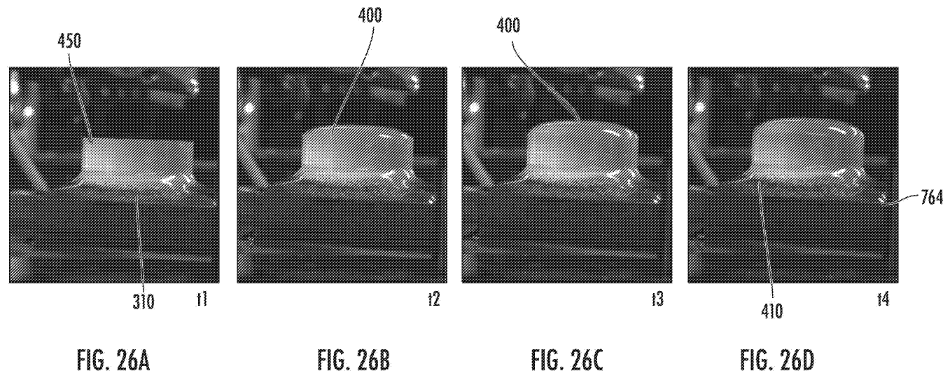

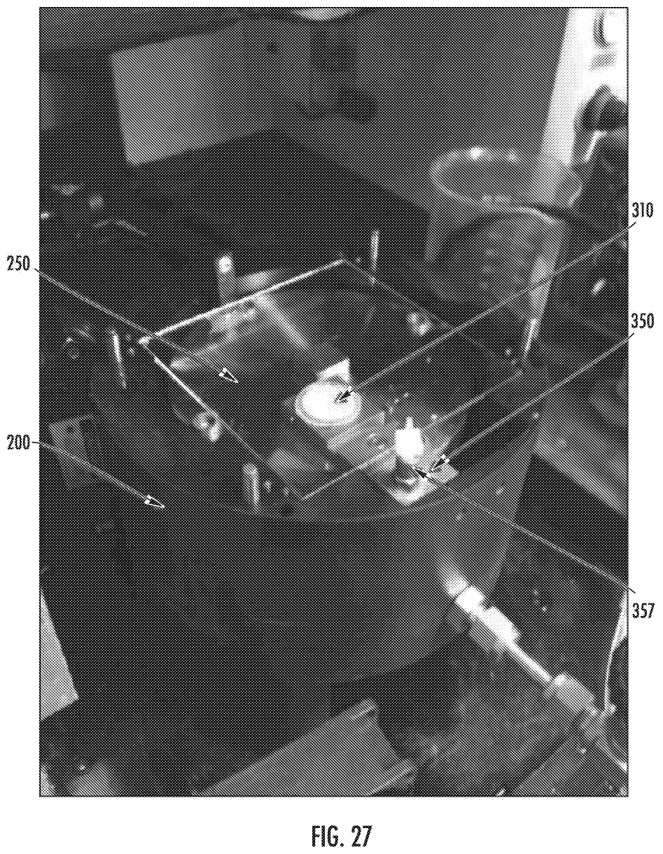

FIGS. 27 and 28 show examples of a microstereolithography device 210 according to an embodiment of the present disclosure. Referring to FIGS. 27 and 28, the microstereolithography device 210 is similar to the device of FIG. 3. The solid boundary 250 is placed over the containment vessel 200 and may comprise a photomask 255 for patterning polymerization light 500. The porous substrate 310 is attached to the substrate holder 350 and the substrate holder 350 includes an injection port 357 for the tube 750. The photomask 255 is arranged to correspond to the porous substrate 310.

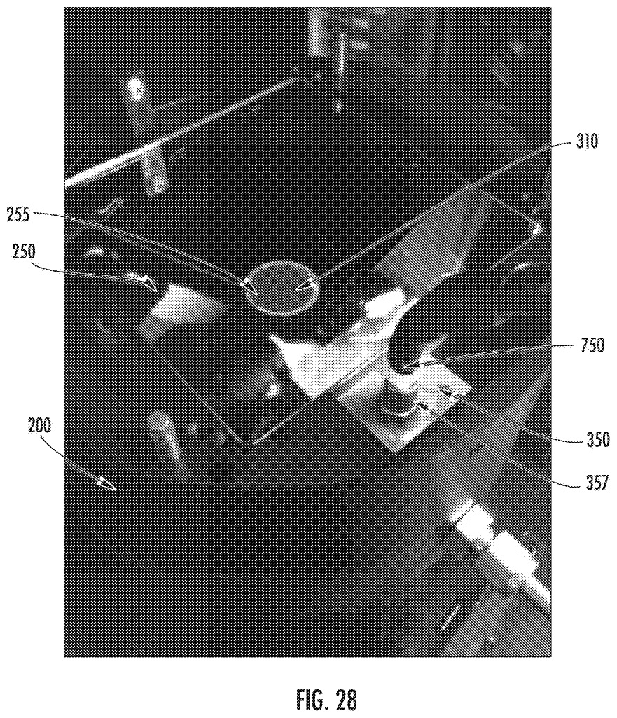

FIG. 29 shows an example of a substrate holder 350 of a microstereolithography device 210 according to an embodiment of the present disclosure. Referring to FIG. 29, the porous substrate 310 is disposed on a top surface of the substrate holder 350, and the pump 730 tubing injection port 357 for the tube 750 is also disposed on the same top surface of the substrate holder 350. The through hole 355 (not shown) can be provided between the pump 730 tubing injection port and the porous substrate 310 such that the liquid monomer 400 provided from the pump 730 tubing injection port is ejected from the porous substrate 310.

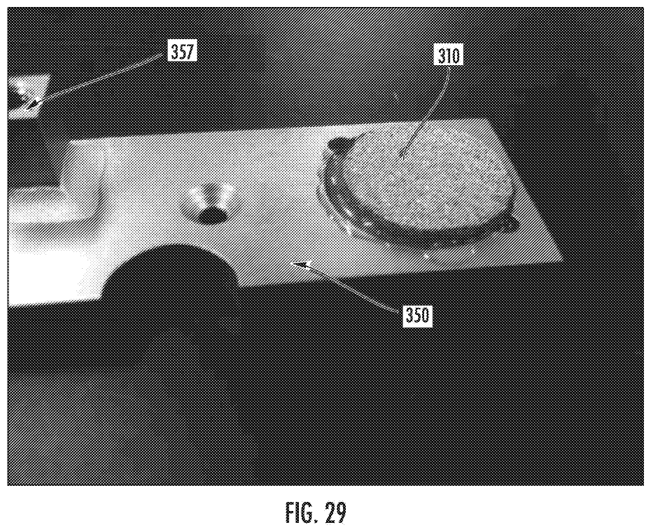

FIG. 30 shows an example of a solid polymer on a microstereolithography device 210 according to an embodiment of the present disclosure. Referring to FIG. 30, the solid polymer 450 is grown from the porous substrate 310 and is attached to the porous substrate 310. In the embodiment illustrated in FIG. 30, the solid polymer 450 includes a plurality of dense empty channels 470.

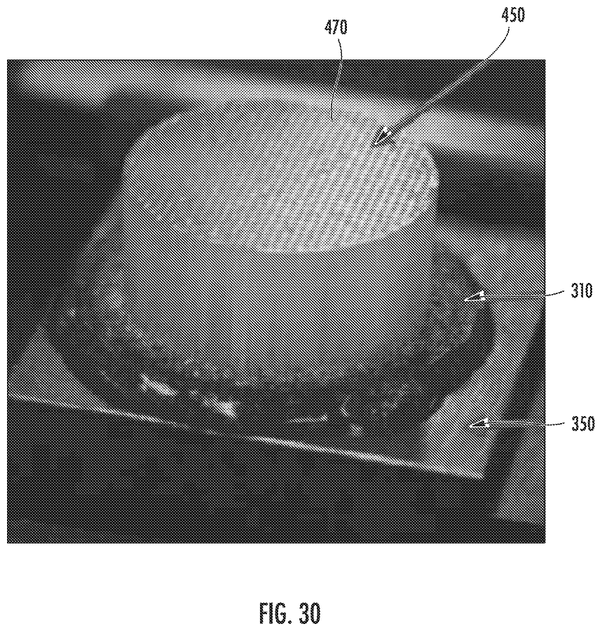

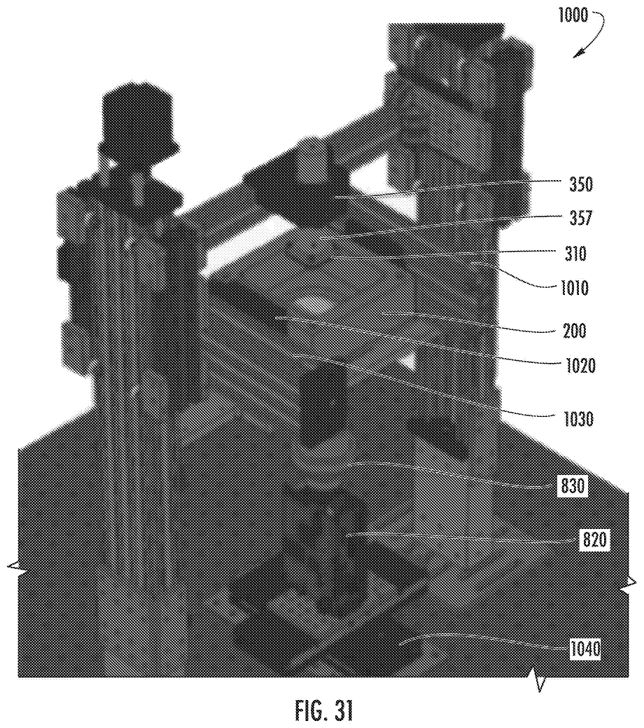

FIGS. 31 and 32 are CAD models of a microstereolithography system for polymerization according to an embodiment of the present disclosure. Referring to FIGS. 31 and 32, the system 1000 comprises a substrate 300 and a substrate holder 350 securing the substrate 300 in a fixed desired position. The substrate holder 350 allows 3 axes (X, Y, and Z) movement of the substrate 300 during setup for auto leveling and fixing the final position prior to fabrication. The substrate 300 can have electrical potential, thereby inducing adhesion of growing solid polymer 450 onto the substrate 300, and reducing stiction at the solid boundary 450. The substrate 300 and the substrate holder 350 can include sensors; such as pressure sensor, force sensor, temperature sensor, accelerometer, and position sensor to detect various fabrication conditions; actuators, and combinations thereof.

The system 1000 shown in FIGS. 31 and 32 includes a lead screw 1050, a stepper motor 1080, Z-axis wheeled rail support system 1070 for reducing deflections, and Z-axis rail movement system 1060 that enable the substrate holder 350 to move in a vertical direction along a Z-axis.

The system 1000 shown in FIGS. 31 and 32 also includes a containment vessel 200 configured to be attached to a bath sliding rail 1010, a bath detachment unit 1020 between the containment vessel 200 and the bath sliding rail 1030, and a bath sliding rail motor 1030 for moving the containment vessel 200. The system 1000 further includes a projection lens 830, a DLP projection system 820 for providing a polymerization light 500, and two axes (X and Y) linear stage 1040.

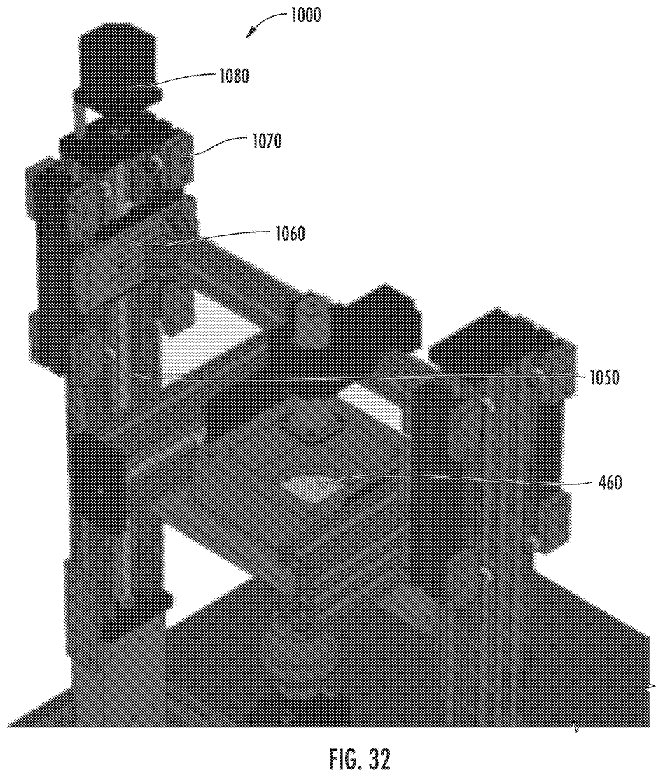

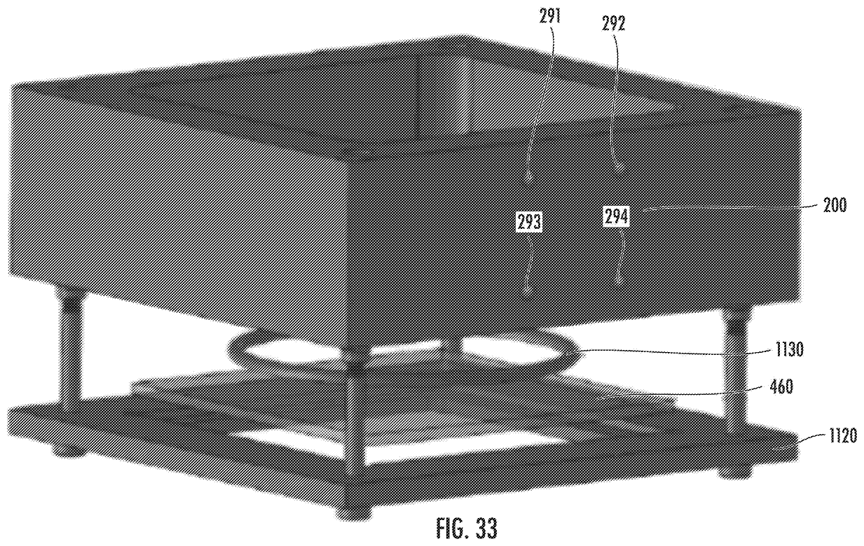

FIGS. 33 and 34 are CAD models of a containment vessel 200 of a microstereolithography device 210 for polymerization according to an embodiment of the present disclosure. Referring to FIGS. 33 and 34, the containment vessel 200, which is configured to contain liquid monomer 400 and secure a solid boundary 250, can be modular and the modular comprises a sealing O-ring 1130, and a solid boundary clamping plate 1120, providing flexibility in choosing and replacing the solid boundary 250. The containment vessel in FIGS. 33 and 34 include inlet/outlet ports such as containment vessel drain ports 291, 292, 293, and 294. The containment vessel 200 can include sensors, such as pressure sensor, force sensor, displacement sensor, temperature sensor, accelerometer, or combinations thereof. In addition, the containment vessel 200 can further include actuators such as piezoelectric actuator and motors.

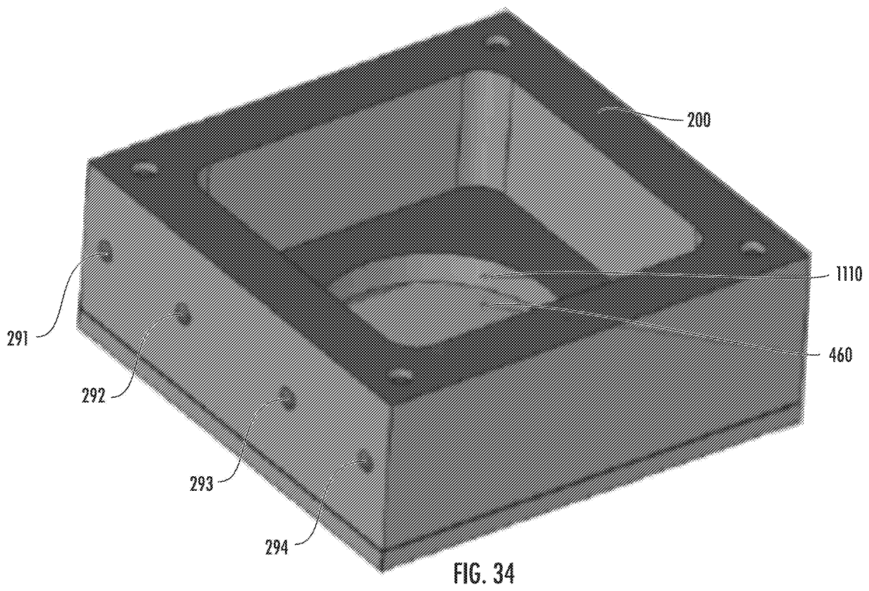

FIG. 35 shows a schematic of an image stitching of a microstereolithography device according to an embodiment of the present disclosure. Referring to FIG. 31, the liquid monomer 400 is polymerized by sequentially exposing unit areas of exposure 1320 to polymerization light 500 (e.g., moving from unit area of exposure 1320 numbered 0 to unit area of exposure 1320 numbered 11), and thus, a high resolution large area image can be manufactured by the image stitching method stitching multiple small area high resolution images into a larger area image. As shown in FIG. 35, the unit areas of exposure 1320 include un-polymerized monomer area 1300 and polymerized monomer area 1310. In an embodiment, the two axes linear stage of FIG. 31 on which the DPL projection system 820 and the projection lens 830 are attached moves in the X axis and Y axis, thereby achieving image stitching. In another embodiment, the XY galvo scanning mirrors 810 of FIG. 5 change the direction of projected polymerization light 500, thereby accomplishing image stitching. In yet another embodiment, the movement of the substrate 300 or the containment vessel 200 in two axes (X and Y) with respect to the projected polymerization light 500 provides image stitching.

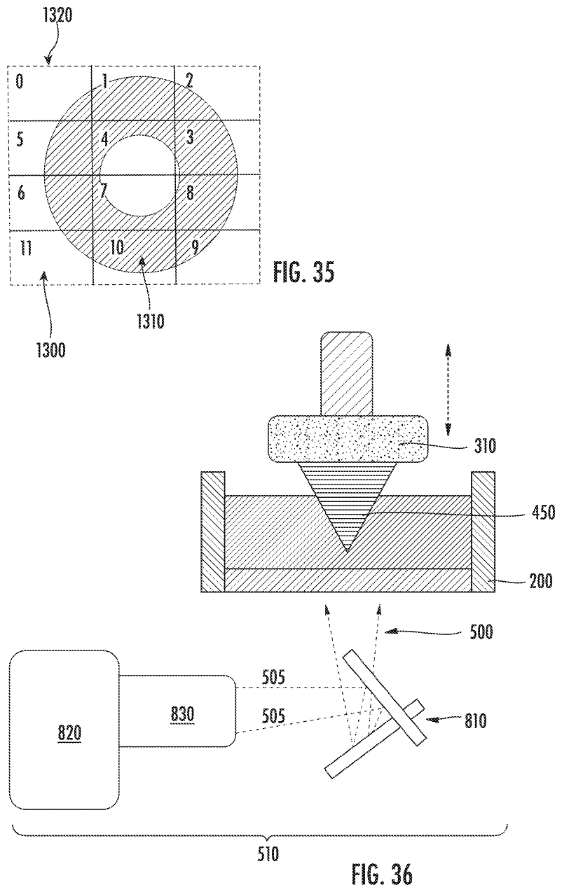

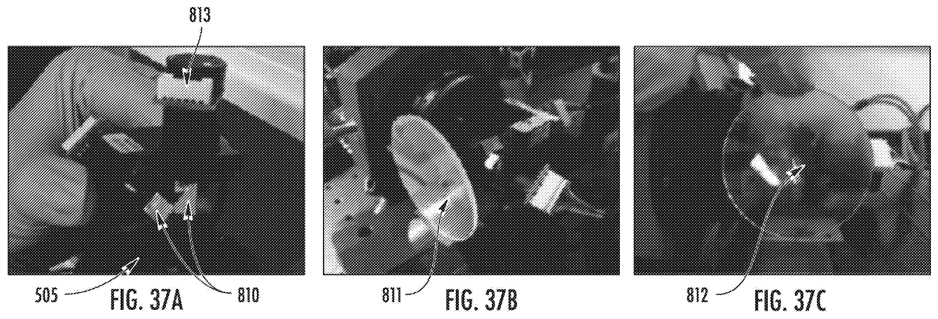

FIG. 36 shows a light source 510 integrating galvo scanning mirrors for image stitching of FIG. 35, and FIGS. 37(a)-37(c) show an example of a light source 510. Referring to FIGS. 36 and 37(a)-37(c), when the DLP 820 emits the light through the projection lens 830, the XY galvo scanning mirrors 810 change the direction of the projected light 505 to polymerization light 500, thereby accomplishing image stitching. After image stitching for one layer of the solid polymer 450, the solid polymer 450 is pulled upwards by Z-axis movement of the porous substrate 310 and then another image stitching for the next layer of the solid polymer 450 is performed by adjusting the XY galvo scanning mirrors 810. FIGS. 37(a)-37(c) also show light 505 being projected onto the XY galvo scanning mirrors 810, the galvo scanning mirror device 813, diffuser 811 to see the projected image, and the projected patterned image 812 which is visible on the diffuser that is being repositioned by the XY galvo scanning mirrors 810.

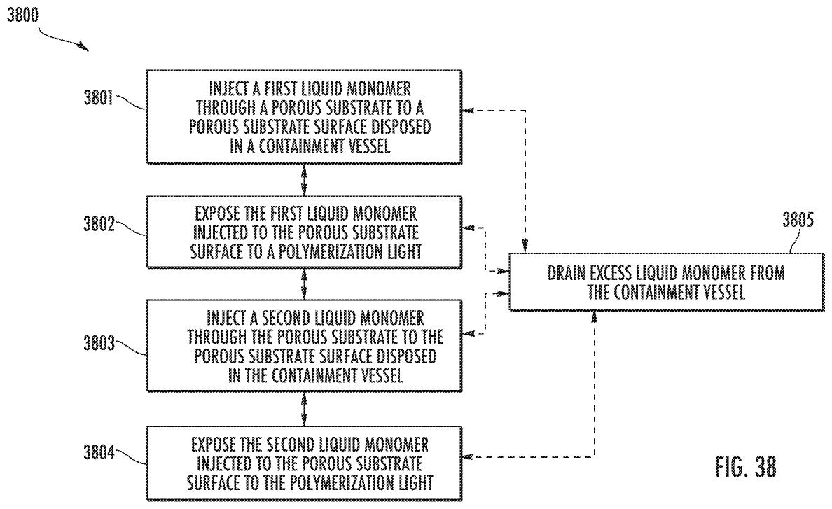

FIG. 38 is a flowchart for an exemplary method in accordance with embodiments disclosed herein. In particular, FIG. 38 illustrates method 3800 which includes injecting a first liquid monomer through a porous substrate to a porous substrate surface disposed in a containment vessel 3801, exposing the first liquid monomer injected to the porous substrate surface to a polymerization light 3802, injecting a second liquid monomer through the porous substrate to the porous substrate surface disposed in the containment vessel 3803, and exposing the second liquid monomer injected to the porous substrate surface to the polymerization light 3804. The method 3800 may also include draining excess liquid monomer from the containment vessel 3805 at any point during the method 3800 (as shown by dotted lines).

In some embodiments, the first and second liquid monomer may be injected simultaneously or sequentially. Further, the first and second liquid monomer may be exposed to polymerization light simultaneously or sequentially.

The present disclosure includes, but is not limited to, the following exemplified embodiments.

Embodiment 1. A device for additive manufacturing, comprising:

a containment vessel; and

a substrate disposed in the containment vessel and having a first substrate surface,

wherein at least a portion of the substrate is a porous substrate and the device is configured to inject a liquid monomer through the porous substrate such that the liquid monomer is polymerized to form a solid polymer on the portion of the substrate that is the porous substrate.

Embodiment 2. The device according to embodiment 1, further comprising a substrate holder attached to the substrate, wherein the substrate holder comprises one or more channels for the liquid monomer to flow through the substrate holder to the substrate.

Embodiment 3. The device according to any of embodiments 1-2, further comprising a liquid monomer reservoir accommodating the liquid monomer, at least one pump providing the liquid monomer to the substrate, and a tube connected to the pump and transferring the liquid monomer from the liquid monomer reservoir to the substrate.

Embodiment 4. The device according to any of embodiments 3, wherein the liquid monomer reservoir comprises a first liquid monomer reservoir and a second liquid monomer reservoir, wherein the first liquid monomer reservoir comprises a first liquid monomer different from a second liquid monomer disposed in the second liquid monomer reservoir.

Embodiment 5. The device according to any of embodiments 1-4, wherein the device is configured to inject a plurality of liquid monomers through the porous substrate.

Embodiment 6. The device according to any of embodiments 3-4, wherein the liquid monomer reservoir comprises a first liquid monomer reservoir and a second liquid monomer reservoir and the pump is configured to provide a first liquid monomer from the first liquid monomer reservoir, a second liquid monomer from the second liquid monomer reservoir, or combinations thereof to the substrate.

Embodiment 7. The device according to any of embodiments 1-6, further comprising a solid boundary disposed opposite the substrate and configured to expose a portion of the liquid monomer to polymerization light passing through the solid boundary.

Embodiment 8. The device according to any of embodiments 1-7, further comprising a light source configured to emit polymerization light to the liquid monomer, wherein the light source spatially controls polymerization of the liquid monomer to the solid polymer.

Embodiment 9. The device according to embodiment 7, wherein the solid boundary includes a photomask, is transparent, or is both transparent and includes a photomask.

Embodiment 10. The device according to any of embodiments 7 and 9, wherein the device includes one or more inlet/outlet ports disposed in the containment vessel, in the solid boundary, or combinations thereof.

Embodiment 11. The device according to any of embodiments 1-10, wherein the device is configured to form a solid polymer comprising one or more channels for liquid monomer to flow through the one or more channels.

Embodiment 12. The device according to any of embodiments 1-11, wherein the porous substrate comprises a plurality of pores disposed equally over the porous substrate and the solid polymer forms over pores of the porous substrate.

Embodiment 13. The device according to any of embodiments 1-12, wherein the solid polymer forms over a portion of the substrate that is non-porous.

Embodiment 14. A method of additive manufacturing comprising:

injecting a first liquid monomer through a porous substrate to a porous substrate surface disposed in a containment vessel;

exposing the first liquid monomer injected to the porous substrate surface to a polymerization light to form a first solid polymer disposed on the porous substrate surface;

injecting a second liquid monomer through the porous substrate to the porous substrate surface disposed in the containment vessel; and

exposing the second liquid monomer injected to the porous substrate surface to the polymerization light to form a second solid polymer disposed on the porous substrate surface.

Embodiment 15. The method according to embodiment 14, wherein the first liquid monomer is different from the second liquid monomer.

Embodiment 16. The method according to any of embodiments 14-15, wherein the second liquid monomer is injected immediately following injection of the first liquid monomer or simultaneously with injection of the first liquid monomer.

Embodiment 17. The method according to any of embodiments 14-16, wherein the containment vessel comprises a solid boundary and injection of the first liquid monomer through the porous substrate forms a liquid bridge disposed between the porous substrate and the solid boundary.

Embodiment 18. The method according to any of embodiments 14-17, wherein the porous substrate comprises a plurality of pores to allow the first liquid monomer and the second liquid monomer to flow through the plurality of pores to multiple locations along the porous substrate surface.

Embodiment 19. The method according to any of embodiments 14-18, further comprising draining excess liquid monomer from the containment vessel through one or more inlet/outlet ports disposed in the containment vessel, a solid boundary disposed in the containment vessel, or combinations thereof.

Embodiment 20. A 3D object formed using the device according to any of embodiments 1-13.

Embodiment 21. A 3D object formed using the method according to any of embodiments 14-19.

It should be understood that the examples and embodiments described herein are for illustrative purposes only and that various modifications or changes in light thereof will be suggested to persons skilled in the art and are to be included within the spirit and purview of this application.

All patents, patent applications, provisional applications, and publications referred to or cited herein are incorporated by reference in their entirety, including all figures and tables, to the extent they are not inconsistent with the explicit teachings of this specification.

What is claimed is:

1. A device for additive manufacturing, comprising:
a containment vessel; and
a substrate disposed in the containment vessel and having a first substrate surface,
wherein at least a portion of the substrate is a porous substrate and the device is configured to inject a liquid monomer through the porous substrate such that the liquid monomer is polymerized to form a solid polymer on the portion of the substrate that is the porous substrate.

2. The device according to claim 1, further comprising a substrate holder attached to the substrate, wherein the substrate holder comprises one or more channels for the liquid monomer to flow through the substrate holder to the substrate.

3. The device according to claim 1, further comprising a liquid monomer reservoir accommodating the liquid monomer, at least one pump providing the liquid monomer to the substrate, and a channel connected to the pump and transferring the liquid monomer from the liquid monomer reservoir to the substrate.

4. The device according to claim 3, wherein the liquid monomer reservoir comprises a first liquid monomer reservoir and a second liquid monomer reservoir, wherein the first liquid monomer reservoir comprises a first liquid monomer different from a second liquid monomer disposed in the second liquid monomer reservoir.

5. The device according to claim 4, wherein the device is configured to inject a plurality of liquid monomers through the porous substrate.

6. The device according to claim 3, wherein the liquid monomer reservoir comprises a first liquid monomer reservoir and a second liquid monomer reservoir and the pump is configured to provide a first liquid monomer from the first liquid monomer reservoir, a second liquid monomer from the second liquid monomer reservoir, or combinations thereof to the substrate.

7. The device according to claim 1, further comprising a solid boundary disposed opposite the substrate and configured to expose a portion of the liquid monomer to polymerization light passing through the solid boundary.

8. The device according to claim 1, further comprising a light source configured to emit polymerization light to the liquid monomer, wherein the light source spatially controls polymerization of the liquid monomer to the solid polymer.

9. The device according to claim 7, wherein the solid boundary includes a photomask, is transparent, or is both transparent and includes a photomask.

10. The device according to claim 7, wherein the device includes one or more inlet/outlet ports disposed in the containment vessel, in the solid boundary, or combinations thereof.

11. The device according to claim 1, wherein the device is configured to form a solid polymer comprising one or more channels for liquid monomer to flow through the one or more channels.

12. The device according to claim 1, wherein the porous substrate comprises a plurality of pores disposed equally over the porous substrate and the solid polymer forms over pores of the porous substrate.

13. The device according to claim 1, wherein the solid polymer forms over a portion of the substrate that is non-porous.

14. A method of additive manufacturing comprising:
injecting a first liquid monomer through a porous substrate to a porous substrate surface disposed in a containment vessel;
exposing the first liquid monomer injected to the porous substrate surface to a polymerization light to form a first solid polymer disposed on the porous substrate surface;
injecting a second liquid monomer through the porous substrate to the porous substrate surface disposed in the containment vessel; and
exposing the second liquid monomer injected to the porous substrate surface to the polymerization light to form a second solid polymer disposed on the porous substrate surface.

15. The method according to claim 14, wherein the first liquid monomer is different from the second liquid monomer.

16. The method according to claim 14, wherein the second liquid monomer is injected immediately following injection of the first liquid monomer or simultaneously with injection of the first liquid monomer.

17. The method according to claim 14, wherein the containment vessel comprises a solid boundary and injection of the first liquid monomer through the porous substrate forms a liquid bridge disposed between the porous substrate and the solid boundary.

18. The method according to claim 14, wherein the porous substrate comprises a plurality of pores to allow the first liquid monomer and the second liquid monomer to flow through the plurality of pores to multiple locations along the porous substrate surface.

19. The method according to claim 14, further comprising draining excess liquid monomer from the containment vessel through one or more inlet/outlet ports disposed in the containment vessel, a solid boundary disposed in the containment vessel, or combinations thereof.

20. A device for additive manufacturing, comprising:
a containment vessel;
a substrate disposed in the containment vessel; and
a solid boundary disposed in the device and opposite the substrate,
wherein the solid boundary defines an inlet/outlet port disposed in the solid boundary for injection of liquid monomer into the containment vessel,
wherein the solid boundary is configured such that liquid monomer injected into the inlet/outlet port disposed in the solid boundary is polymerized to form a solid polymer when exposed to polymerization light through the solid boundary.
